(19) United States
(12) Patent Application Publication
(10) Pub. No.: US 2009/0072871 A1
(43) Pub. Date: Mar. 19, 2009

(54) VARIABLE DELAY CIRCUIT, DELAY TIME CONTROL METHOD AND UNIT CIRCUIT

(75) Inventor: Noriyuki TOKUHIRO, Kawasaki (JP)

Correspondence Address: STAAS & HALSEY LLP, SUITE 700, 1201 NEW YORK AVENUE, N.W., WASHINGTON, DC, 20005, US

(73) Assignee: FUJITSU LIMITED, Kawasaki (JP)

(21) Appl. No.: 12/203,528

(22) Filed: Sep. 3, 2008

(30) Foreign Application Priority Data
Sep. 18, 2007 (JP) 2007-241611

(51) Int. Cl. H03L 7/06

(52) U.S. Cl. 327/158

(57) ABSTRACT

Variable delay circuit constructed by connecting plural unit circuits in series which can change a delay time from input of signal until output of the signal by increasing or decreasing the number of unit circuits through which the signal concerned is passed. Each of the unit circuits is operable in a through operation mode in which a signal input from a unit circuit at the front stage is output to a unit circuit at the rear stage and also a signal input from a unit circuit at the rear stage is output to a unit circuit at the front stage and a feedback operation mode in which a signal input from a unit circuit at the front stage to a unit circuit at the front stage and a signal input from a unit circuit at the rear stage is output to a unit circuit at the rear stage.

### CROSS-REFERENCE TO RELATED APPLICATIONS

This application is related to and claims priority to Japanese patent application no. 2007-241611 filed on Sep. 18, 2007, in the Japan Patent Office, and incorporated by reference herein.

### BACKGROUND

1. Field

The circuit relates to a technique of setting a delay time from the input time of a signal until the output time of the signal.

2. Description of the Related Art

The speed of memory interfaces has increased year by year as memory interfaces have been recently developed. An example is the DDR 3 (Double Data Rate 3) memory interface, etc. which is standardized in JEDEC (Joint Electron Device Engineering Council).

A DLL (Delay Locked Loop) is indispensable when such a memory interface is designed. A variable delay circuit that can change the delay time from input of a signal to output of the signal is used in the DLL (for example, see JP-A-2005-286467).

Means for implementing the variable delay circuit is roughly classified into an analog type and a digital type. According to the analog type, the delay time of an input signal is set in an analog style by varying the power supply voltage or load of the circuit in an analog style. On the other hand, according to the digital type, the delay time of an input signal is set by switching the signal path of the circuit in a digital style.

Here, it is known that minute variation of the delay time can be created in the analog type. Fluctuations of the delay time, however, are generated by noise. Therefore, the digital type variation delay circuit, which is hardly affected by noise, has been generally used at present.

FIG. 1 is a diagram showing an example of the construction of a conventional variable delay circuit. FIGS. 2A to 2C are diagrams showing an example of the circuit construction of a conventional unit circuit. FIG. 2A is a diagram showing the construction of the unit circuit, FIG. 2B is a diagram showing a through operation mode of the unit circuit, and FIG. 2C is a diagram showing a return operation mode of the unit circuit.

The specific construction of the conventional variable delay circuit 90 will be described with reference to FIGS. 1 and 2.

As shown in FIG. 1, the conventional variable delay circuit 90 is constructed by connecting plural (ten in the example shown in FIG. 1) unit circuits 91-1 to 91-10 in series.

The circuits are represented by reference numerals 91-1 to 91 when it is necessary to specify one of the plural unit circuits. The circuits are represented by reference numeral 91, however, when any unit circuit is indicated.

The unit circuit 91 is designed so that a terminal for outputting an input signal can be switched. The unit circuit 91 has a control signal input terminal CONT, a selector 92, a first input terminal IN-1, a second input terminal IN-2, a first output terminal OUT-1 and a second output terminal OUT-2 as shown in FIG. 2A.

The control signal input terminal CONT is a terminal to which a control signal is input from CPU (Central Processing Unit; not shown) or the like. The control signal input terminal CONT is connected to the selector 92 described later.

The selector 92 switches the signal to be output on the basis of the control signal input to the control signal input terminal CONT. The selector 92 has two input terminals and one output terminal.

The first input terminal IN-1 is a terminal to which a signal is input. The first input terminal IN-1 is connected to one input terminal of the selector 92 and the first output terminal OUT-1 through an amplifier 93-1.

The second input terminal IN-2 is a terminal to which a signal is input. The second input terminal IN-2 is connected to the other input terminal of the selector 92.

The first output terminal OUT-1 is a terminal which outputs the signal input to the first input terminal IN-1. The second output terminal OUT-2 is a terminal which outputs the signal input to the first input terminal IN-1 through an amplifier 93-2.

Furthermore, the unit circuit 91 is designed so that the through operation mode and the return operation mode can be selectively operated on the basis of the control signal from the control signal input terminal CONT.

In the through operation mode, the signal input from the first input terminal IN-1 is output to the first output terminal OUT-1, and also the signal input from the second input terminal IN-2 is output to the second output terminal OUT-2 as shown in FIG. 2B. In the return operation mode, the signal input from the first input terminal IN-1 is output to the second output terminal OUT-2 and the first output terminal OUT-1.

Furthermore, in the variable delay circuit 91, as shown in FIG. 1, the plural unit circuits 91-1 to 91-10 are connected to one another in series. The adjacent unit circuits 91 are designed so that the first input terminal IN-1 and the first output terminal OUT-1 are connected to each other and the second input terminal IN-2 and the second output terminal OUT-2 are connected to each other.

That is, in the through operation mode, the signal input from the unit circuit 91 at the front stage is output to the unit circuit 91 at the rear stage, and also the signal input from the unit circuit 91 at the rear stage is output to the unit circuit 91 at the front stage. In the return operation mode, the signal input from the unit circuit 91 at the front stage is output to the unit circuit 91 at the front stage.

The delay time from an input time of a signal to an output time of a signal can be changed by increasing or reducing the number of unit circuits 91 through which the signal is passed. The number of unit circuits 91 through which the signal input to the first input terminal IN-1 of the unit circuit 91-1 at the forefront stage is passed is increased/reduced on the basis of the control signal input from CPU or the like to the respective control signal input terminals CONT of the respective unit circuits 91-1 to 91-10 by the variable delay circuit 90.

For example, when an High signal is input as a control signal to the control signal input terminal CONT of the unit circuit 91-8 of the variable delay circuit 90 as shown in FIG. 1, and a Low signal is input as a control signal to the control signal input terminal CONT of each of the unit circuits 91-1 to 91-7, 91-9, 91 -1 0 other than the unit circuit 91-8, the unit circuit 91-8 operates in the return operation mode, and the unit circuits 91-1 to 91-7, 91-9, 91-10 operate in the through operation mode, thereby forming a signal passing line.

The signal passing line is formed as follows. That is, as shown in FIG. 1, a signal input to the first input terminal IN-1 of the unit circuit 91-1 at the forefront stage is successively passed through the plural unit circuits 91-2 to 91-7 operating in the through operation mode from the unit circuit 91-2 to the unit circuit 91-7. The signal is then returned from the unit circuit 91-8 operating in the return operation mode. Thereafter, the signal is successively passed through the plural unit circuits 91-2 to 91-7 operating in the through operation mode from the unit circuit 91-7 to the unit circuit 91-2 and then output from the second output terminal OUT-2 of the unit circuit 91-1 at the forefront stage.

As described above, in the variable delay circuit described above, the unit circuits operating in the return operation mode are changed to thereby increase/reduce the number of the unit circuits through which the signal passes (propagates), thereby changing the delay time from the input of the signal to the output of the signal concerned.

### SUMMARY

Variable delay circuit constructed by connecting plural unit circuits in series which can change a delay time from input of signal until output of the signal by increasing or decreasing the number of unit circuits through which the signal concerned is passed. Each of the unit circuits is operable in a through operation mode in which a signal input from a unit circuit at the front stage is output to a unit circuit at the rear stage and also a signal input from a unit circuit at the rear stage is output to a unit circuit at the front stage and a feedback operation mode in which a signal input from a unit circuit at the front stage to a unit circuit at the front stage and a signal input from a unit circuit at the rear stage is output to a unit circuit at the rear stage.

Additional objects and advantages of the embodiment will be set forth in part in the description which follows, and in part will be obvious from the description, or may be learned by practice of the embodiment. The object and advantages of the embodiment will be realized and attained by means of the elements and combinations particularly pointed out in the appended claims.

It is to be understood that both the foregoing general description and the following detailed description are exemplary and explanatory only and are not restrictive of the embodiment, as claimed.

### BRIEF DESCRIPTION OF THE DRAWINGS

FIG. 1 is a diagram showing a construction example of a conventional variable delay circuit;

FIGS. 2A to 2C are diagrams showing an example of the circuit construction of a conventional unit circuit;

FIG. 3 is a diagram showing an example in which a signal input to the conventional variable delay circuit is returned from the unit circuit at the third stage and then output from the variable delay circuit;

FIG. 4 is a diagram showing an example of the construction of an information processing device according to a first embodiment;

FIG. 5 is a diagram showing an example of the circuit construction of a memory controller corresponding to SDRAM-1 of the information processing device according to the first embodiment;

FIG. 6 is a diagram showing an example of the circuit construction of a memory controller corresponding to SDRAM-n of the information processing device according to the first embodiment;

FIG. 7 is a diagram showing a write leveling function in a first delay time controller of the information processing device according to the first embodiment;

FIG. 8 is a diagram showing a calculation equation of calculating a first delay time in the first delay time controller of the information processing device according to the first embodiment;

FIG. 9 is a diagram showing a calculation equation of determining the first delay time in the first delay time controller of the information processing device according to the first embodiment;

FIG. 10 is a diagram showing a write operation using the first variable delay circuit of the information processing device according to the first embodiment;

FIG. 11 is a diagram showing a read operation using a second variable delay circuit of the information processing device according to the first embodiment;

FIG. 12 is a circuit diagram showing a part corresponding to SDRAM-1 of the memory controller of the information processing device according to a modification of the first embodiment;

FIG. 13 is a circuit diagram showing a part corresponding to SDRAM-n of the memory controller of the information processing device according to the modification of the first embodiment;

FIG. 14 is a circuit diagram showing a part corresponding to SDRAM-1 of the memory controller of the information processing device according to a second embodiment;

FIG. 15 is a circuit diagram showing a part corresponding to SDRAM-n of the memory controller of the information processing device according to the second embodiment;

FIG. 16 is a diagram showing the function of a third variable delay circuit of the memory controller of the information processing device according to the second embodiment;

FIG. 17 is a diagram showing the construction example of the third variable delay circuit of the information processing device according to the second embodiment;

FIGS. 18A to 18C are diagrams showing the construction example of a unit circuit of the third variable delay circuit of the information processing device according to the second embodiment;

FIG. 19 is a circuit diagram showing a part corresponding to SDRAM-1 of the memory controller of the information processing device according to a modification of the second embodiment;

FIG. 20 is a circuit diagram showing a part corresponding to SDRAM-n of the memory controller of the information processing device according to the modification of the second embodiment; and

FIG. 21 is a diagram showing another use example of the third variable delay circuit in the information processing device according to other embodiments of the present circuit.

### DETAILED DESCRIPTION OF THE PREFERRED EMBODIMENTS

Embodiments will be described with reference to the accompanying drawings. Reference may now be made in detail to embodiments, examples of which are illustrated in the accompanying drawings, wherein like reference numerals refer to like elements throughout.

### Description of First Embodiment

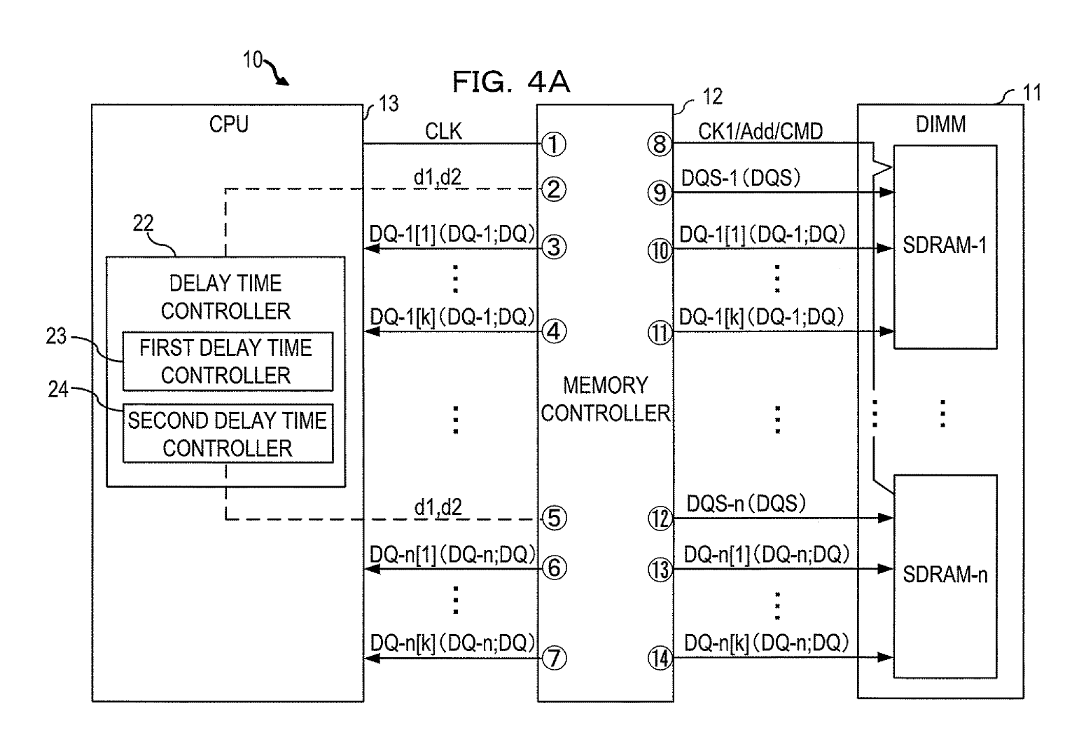

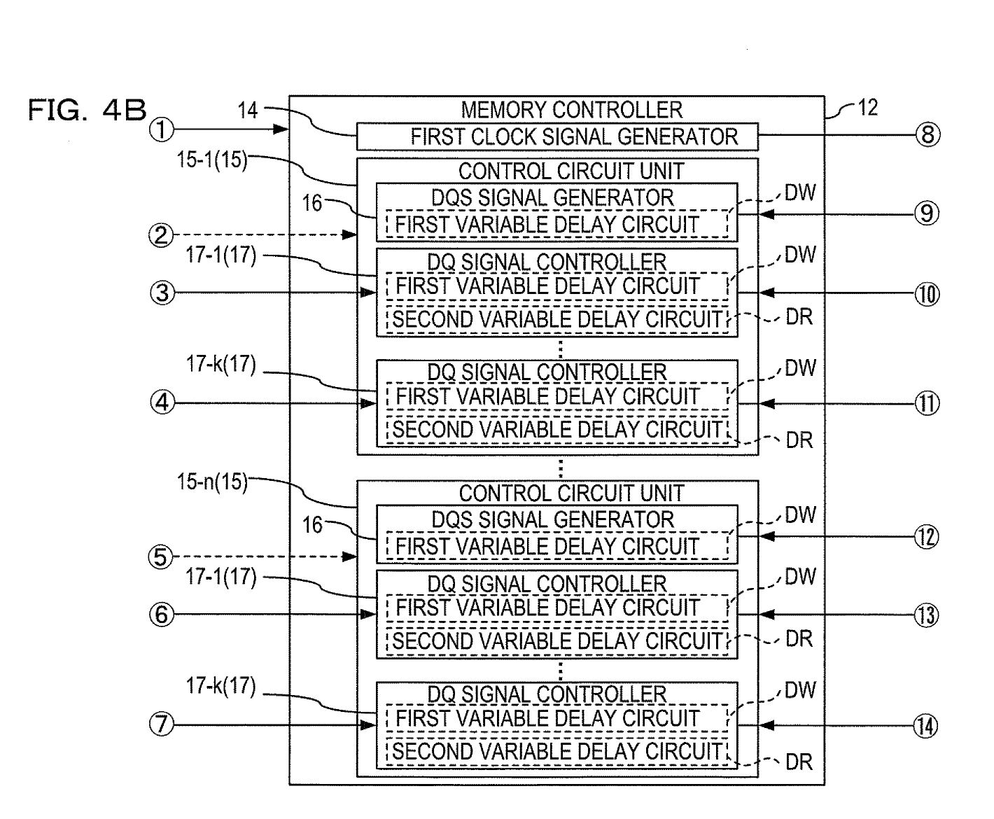

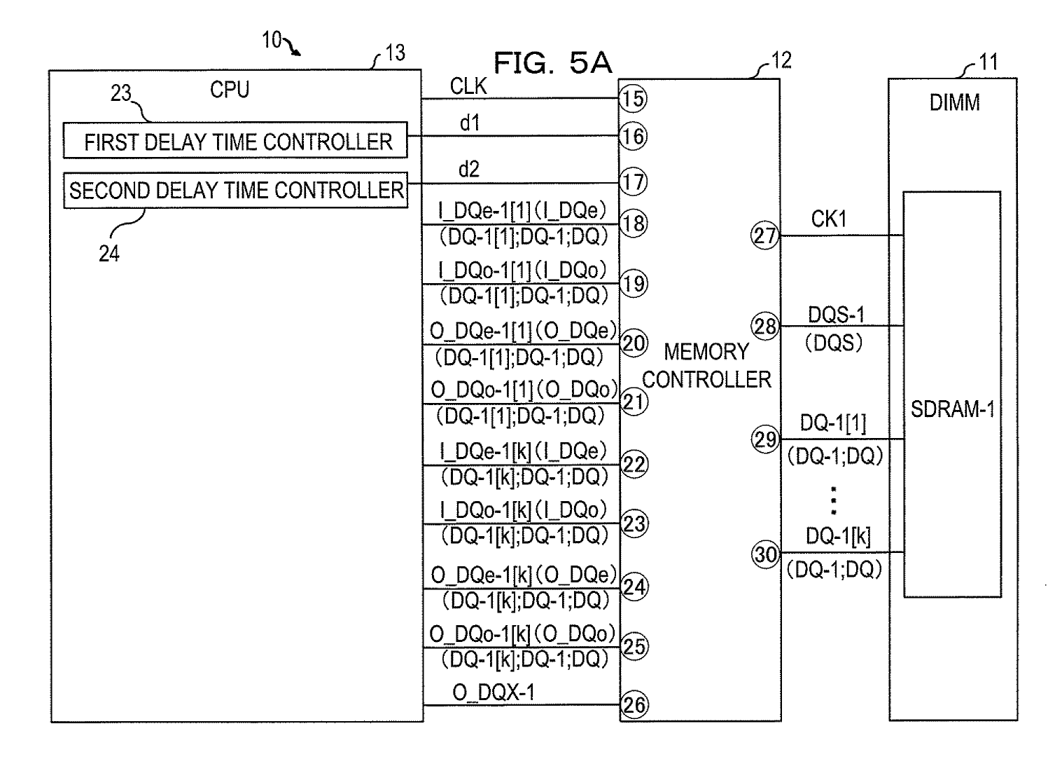

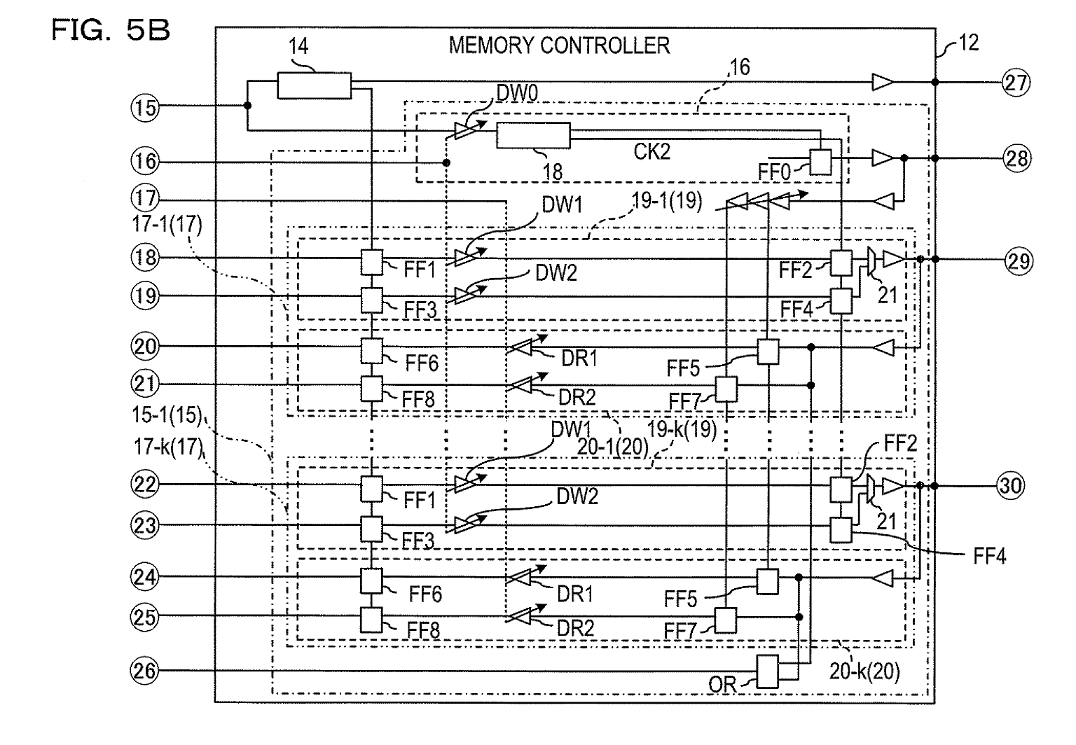

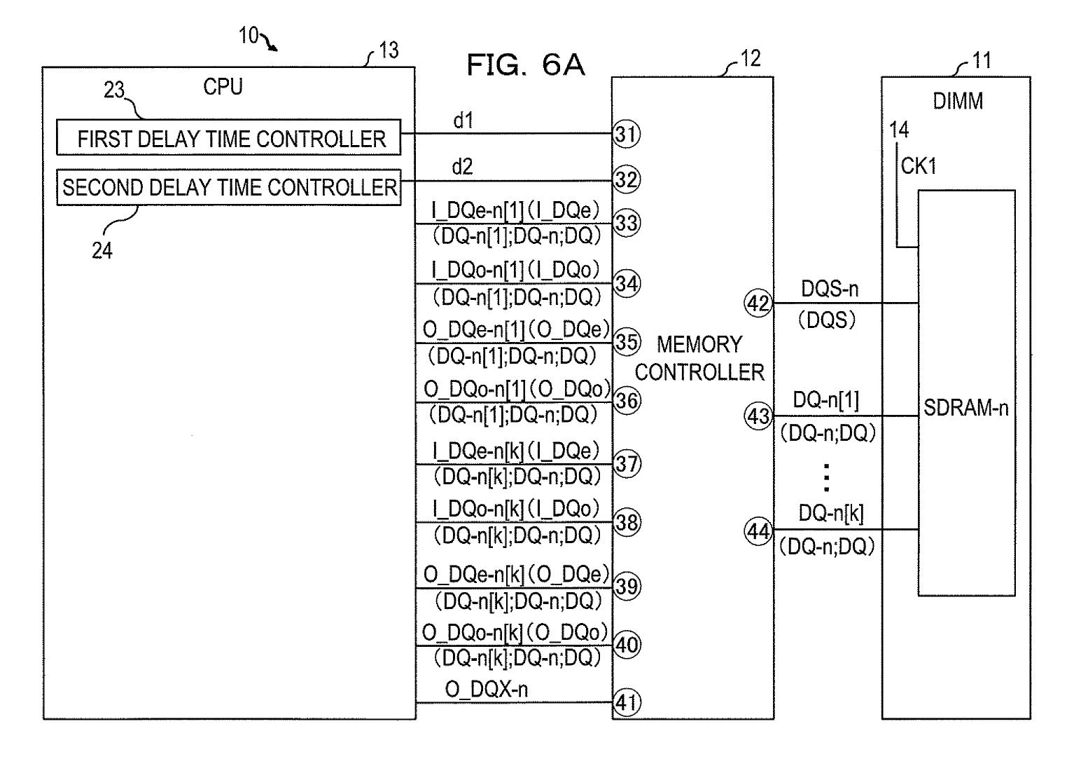

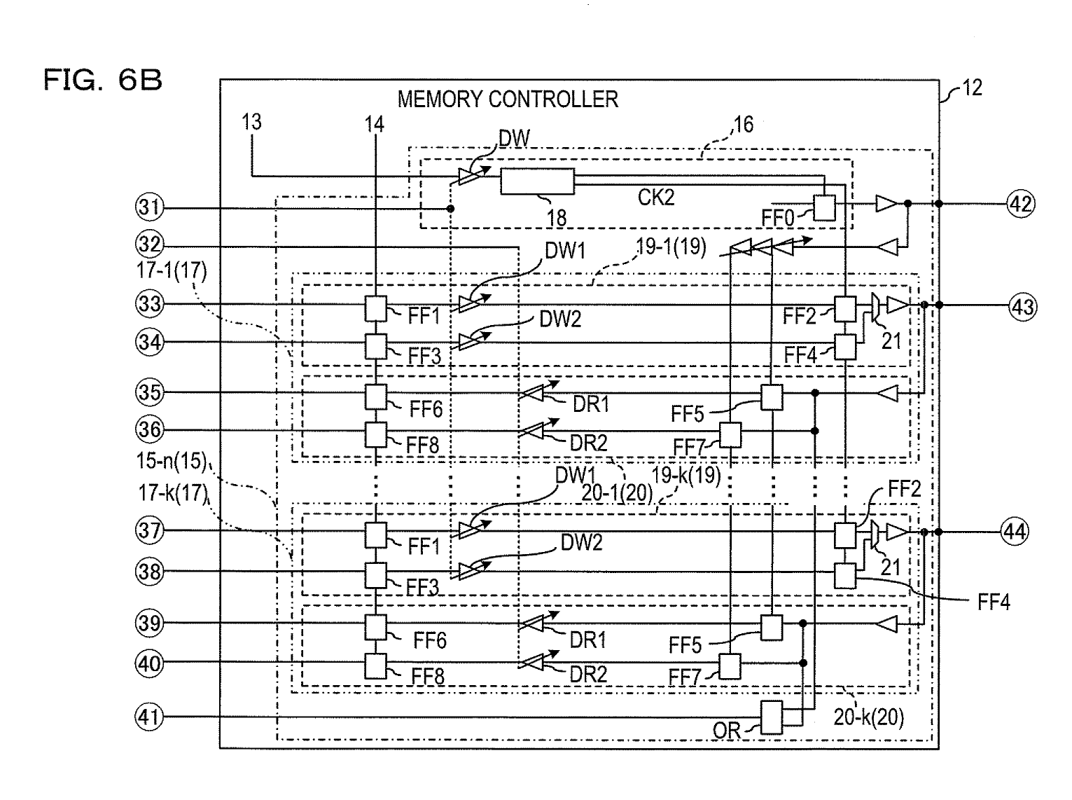

FIG. 4 is a diagram showing an example of the construction of an information processing device according to a first embodiment. FIG. 5 is a diagram showing an example of the circuit construction of a memory controller corresponding to SDRAM-1. FIG. 6 is a diagram showing an example of the circuit construction of a memory controller corresponding to SDRAM-n.

As a shown in FIG. 4, an information processing device (delay time control device) according to the first embodiment is constructed as a computer having DIMM (Dual Inline Memory Module) 11, a memory controller (memory control circuit) 12 and CPU (Central Processing Unit) 13.

DIMM 11 is a memory module having plural memories mounted therein. A DIMM 11 is constructed by plural (n; n represents a natural number of 2 or more) SDRAM (Synchronous DRAM; memory)-1 to SDRAM-n in this embodiment) as shown in FIG. 4. Furthermore, n represents the number of ch (channels) and it is represented by only SDRAM-1 and SDRAM-n for convenience of description in FIG. 4. SDRAM is a well-known technique, and the detailed description thereof is omitted.

In the following description, when it is necessary to specify one of plural SDRAMs, it is represented by appending “-(hyphen)” and reference numeral 1 to n subsequently to reference character “SDRAM”. However, when any SDRAM is indicated, it is merely represented by SDRAM.

In this embodiment, flyby topology is adopted for the wiring between the memory controller 12 and the plural SDRAM-1 to SDRAM-n.

The flyby topology means that some wires of the memory controller 12 and the plural SDRAM-1 to SDRAM-n are subjected to daisy chain connection.

Accordingly, in this embodiment, a clock signal line for outputting (supplying) a clock signal CK1 generated by a first clock signal generator 14 (described later) is wired to SDRAM-1 to SDRAM-n by daisy chain connection. As shown in FIG. 4, SDRAMs from SDRAM-1 to SDRAM-n are strung together by the clock signal line connected to the first clock signal generator 14 like beads. As in the case of the clock signal line, an address signal Add and a signal line for outputting a command signal CMD are also wired to SDRAM-1 to SDRAM-n by daisy chain connection.

Data signal lines through which the memory controller 12 is connected to the plural SDRAM-1 to SDRAM-n are connected from the memory controller 12 to the plural SDRAM-1 to SDRAM-n in parallel. In the example of FIG. 5, one DQS signal line (data signal line) for transmitting a data strobe signal DQS and DQ signal lines (data signal lines) of k (k represents a natural number of 2 or more) for transmitting data signals DQ are connected from the memory controller 12 to the plural SDRAM-1 to SDRAM-n in parallel. These data signal lines are designed to have the same line length (equal length). That is, the plural data signal lines through which the memory controller 12 is connected to the plural DSRAM-1 to SDRAM-n are connected isometrically (equally in length).

The memory controller 12 serves as a DDR3 (Double Data Rate 3) memory interface for controlling the read/write operation by supplying a clock signal CK through the clock signal line to the plural SDRAM-1 to SDRAM-n to which the clock signal line is connected by the daisy chain connection. For example, as shown in FIG. 4, the memory controller 12 is equipped with a first clock signal generator 14 and plural control circuit units 15-1 to 15-n.

Furthermore, the memory controller 12 is provided with a write leveling function. The details of the write leveling function will be described later.

The plural control circuit units 15-1 to 15-n are constructed in connection with the respective plural SDRAM-1 to SDRAM-n. That is, the memory controller 12 is equipped with the control circuit unit 15-1 corresponding to SDRAM-1 and the control circuit unit 15-n corresponding to SDRAM-n as shown in FIG. 4, for example.

With respect to the reference numeral representing the control circuit unit in the following description, when it is necessary to specify one of the plural control circuit units, “-(hyphen)” and reference numerals 1 to n are used after the reference numeral 15. However, when any control circuit unit is indicated, the reference numeral 15 is used.

In the drawings, only the control circuit unit 15-1 and the control circuit unit 15-n are shown for convenience of description.

The first clock signal generator 14 generates/outputs a clock signal CK1 of a predetermined period on the basis of a clock signal CLK input from CPU 13 described later, and it outputs the clock signal CK1 through the clock signal line to DIMM 11 (SDRAM-1 to SDRAM-n) as shown in FIGS. 5 and 6, for example. In addition, it outputs the clock signal CK1 to the plural control circuit units 15-1 to 15-n. The first clock signal generator 14 may output a clock signal having the same clock period as the clock signal CLK as the clock signal CK1, or may output a clock signal CK1 obtained by converting the clock period of the clock signal CLK to another clock period such as a half period, a quarter period or the like.

The control circuit unit 15 controls input/output of a data strobe signal DQS or data signal DQ, and for example it is equipped with a DQS signal generator 16, plural (k; k represents a natural number of 2 or more) DQ signal controllers 17-1 to 17-k and a logical addition circuit OR (see FIGS. 5, 6).

With respect to the reference numeral representing the DQ signal controller in the following description, when it is necessary to specify one of the DQ signal controllers, “-(hyphen)” and reference numerals 1 to k are used subsequently to the reference numeral 17. However, any DQ signal controller is indicated, the reference numeral 17 is used.

In the drawings, only the DQ signal controller 17-1 and the DQ signal controller 17-k are shown for the convenience of description.

The DQS signal generator 16 generates a data strobe signal DQS, and the control circuit unit 15 is equipped with one DQS signal generator 16. For example, the control circuit unit 15-1 generates a data strobe signal DQS-1 and outputs it to SDRAM-1 as shown in FIG. 5. Furthermore, the control circuit unit 15-n generates a data strobe signal DQS-n and outputs it to SDRAM-n as shown in FIG. 6.

With respect to the reference numeral representing the data strobe signal, when it is necessary to specify one of plural data strobe signals, reference characters DQS-1 to DQS-n are used. However, when any data strobe signal is indicated, reference character DQS is used.

For example, this DQS signal generator 16 is equipped with a first variable delay circuit (first variable delay unit) DW0, a second clock signal generator 18 and a flip flop FF0 as shown in FIGS. 5 and 6.

The first variable delay circuit DW0 delays the clock signal CLK input from CPU 13 described later by only a predetermined time on the basis of a first control signal d1 from a first delay time controller 23 described later and outputs the delayed clock signal CLK. For example, the clock signal CLK input from CPU 13 described later is delayed by only the first delay time set in the first delay time controller 23 described later and then output to the second clock signal generator 18.

In this embodiment, the first delay time is set to each of the plural control circuit units 15-1 to 15-n. Specifically, a first delay time Dt1-1 is set in the first variable delay circuit DW0 of the control circuit unit 15-1, and likewise a first delay time Dt1-n is set in the first variable delay circuit DW0 of the control circuit unit 15-n.

With reference to reference numeral representing the first delay time, reference numerals Dt1-1 to Dt1-n are used when it is necessary to individually each of the plural first delay times. However, when any first delay time is indicated, reference numeral Dt1 is used.

The second clock signal generator 18 generates/outputs (supplies) a clock signal CK2 on the basis of the clock signal CLK input from CPU 13 described later. For example, as shown in FIGS. 5 and 6, when the clock signal CLK is input, the clock signal CK2 of a predetermined period is output to the flip flop FF0 and flip flops FF2, FF4 described later. The second clock signal generator 18 may output the clock signal having the same clock period as the clock signal CLK as the clock signal CK2, or may output the clock signal CK2 obtained by converting the clock period of the clock signal CLK to another clock period such as a half period, a quarter period or the like.

The flip flop FF0 generates a data strobe signal DQS on the basis of the clock signal CK2 input from the second clock signal generator 18 and outputs it. For example, as shown in FIGS. 5 and 6, when the clock signal CK2 is input, it generates a data strobe signal DQS and outputs it to SDRAM.

The DQ signal controller 17 controls the input/output of the data signal DQ. The DQ signal controller 17 is constructed by a DQ signal input controller 19 and a DQ signal output controller 20 as shown in FIGS. 5 and 6. Specifically, as shown in FIGS. 5 and 6, in each of the plural (n) control circuit units 15-1 to 15-n, the DQ signal controller 17-1 is equipped with a DQ signal input controller 19-1 and a DQ signal output controller 20-1. Likewise, the DQ signal controller 17-k is equipped with a DQ signal input controller 19-k and a DQ signal output controller 20-k.

With respect to the reference numeral representing the DQ signal input controller, when it is necessary to individually each of the plural (k) DQ signal input controllers, reference numerals 19-1 to 19-k are used. However, when any DQ signal input controller is indicated, reference numeral 19 is used. Furthermore, with respect to the reference numeral representing the DQ signal output controller, when it is necessary to individually each of the plural DQ signal output controllers, reference numerals 20-1 to 20-k are used. However, when any DQ signal output controller is indicated, reference numeral 20 is used.

The DQ signal input controller 19 carries out the control of outputting the data signal DQ input from CPU 13 described later to SDRAM in the write operation. For example, in the control circuit unit 15-1, in connection with plural (k) DQ signal input controllers 19-1 to 19-k, first data signal I_DQe-1[1] and second data signal I_DQo-1[1] input from CPU 13 described later are controlled to be output as data signal DQ-1[1] to SDRAM-1 as shown in FIG. 5. Likewise, first data signal I_DQe-1[k] and second data signal I_DQo-1[k] input from CPU 13 described later are controlled to be output as data signal DQ-1[k] to SDRAM-1.

Furthermore, in the control circuit unit 15-n, the DQ signal input controller 19 controls to output first data signal I_DQe-n[1] and second data signal I_DQo-n[1] input from CPU 13 described later as data signal DQ-n[1] to SDRAM-n in connection with the plural DQ signal controllers 19-1 to 19-k as shown in FIG. 6. Likewise, first data signal I_DQe-n[k] and second data signal I_DQo-n[k] input from CPU 13 described later are controlled to be output as data signal DQ-n[k] to SDRAM-n.

With respect to reference character representing the first data signal, when it is necessary to specify one of the plural first data signals, reference characters I_DQe-1[1] to I_DQe-1[k] and reference characters I_DQe-n[1] to I_DQe-n[k] are used. However, when any first data signal is indicated, reference character I_DQe is used. Furthermore, with respect to reference character representing the second data signal, when it is necessary to specify one of the plural data signals, reference characters I_DQo-1[1] to I_DQo-1[k], I_DQo-n[1] to I_DQo-n[k] are used. However, when any second data signal is indicated, reference character I_DQo is used.

In the case where the data signal is represented, when it is necessary to specify the first data signal and the second data signal, the reference characters I_DQe and I_DQe-1[1] to I_DQe-1[k], I_DQe-n[1 ] to I_DQe-n[k] which represent the first data signal and the reference characters I_DQo and I_DQo-1[1 ] to I_DQo-1[k], I_DQo-n[1 ] to I_DQo-n[k] which represent the second data signal are used. On the other hand, when it is unnecessary to specify the first data signal and the second data signal, the reference characters DQ-1[1] to DQ-1[k], DQ-n[1] to DQ-n[k] representing the data signals corresponding to SDRAM-1 to SDRAM-n respectively are used, and further when any data signal is indicated, the reference character DQ is used. In the case where it is unnecessary to specify the first data signal and the second data signal, the reference characters DQ-1 to DQ-n may be used in place of the reference characters DQ-1[1] to DQ-1[k], DQ-n[1] to DQ-n[k] representing the data signals corresponding to SDRAM-1 to SDRAM-n.

That is, the first data signals I_DQe-1[1] to I_DQe-1[k] corresponding to SDRAM-1 correspond to the first data signal I_DQe, the data signals DQ-1[1] to DQ-1[k], the data signal DQ-1 and the data signal DQ, and the first data signals I_DQe-n[1] to I_DQe-n[k] corresponding to SDRAM-n correspond to the first data signal I_DQe, the data signals DQ-n[1] to DQ-n[k], the data signal DQ-n and the data signal DQ. The second data signals I_DQo-1[1] to I_DQo-1[k] corresponding to SDRAM-1 correspond to the second data signal I_DQo, the data signal DQ-1[1] to DQ-1[k], the data DQ-1 and the data signal DQ, and the second data signals I_DQo-n[1] to I_DQo-n[k] corresponding to SDRAM-n correspond to the second data signal I_DQo, the data signal DQ-n[1] to DQ-n[k], the data DQ-n and the data signal DQ.

For example, the DQ signal input controller 19 is equipped with a flip flop FF1, a first variable delay circuit (first variable delay unit) DW1, a flip flop FF2, a flip flop FF3, a first variable delay circuit (first variable delay unit) DW2 and a flip flop FF4 as shown in FIGS. 5 and 6.

When the clock signal CK1 input from the first clock signal generator 14 is input, the flip flop FF1 outputs the first input data signal I_DQe input from CPU 13 described later to the first variable delay circuit DW1.

The first variable delay circuit DW1 is a digital delay circuit for delaying the first input data signal I_DQe input from the flip flop FF1 on the basis of the first control signal d1 input from the first delay controller 23 described later and then outputting the delayed first input data signal I_DQe to the flip flop FF2. For example, the first input data signal I_DQe input from the flip flop FF1 is delayed by only the first delay time Dt1 set in the first delay time controller 23 described later, and then output to the flip flop FF2.

When the clock signal CK2 is input from the second clock signal generator 18, the flip flop FF2 outputs the first input data signal I_DQe input from the first variable delay circuit DW1 to SDRAM through a selector 21.

When the clock signal CK1 is input from the first clock signal generator 14, the flip flop FF3 outputs the second input data signal I_DQo input from CPU 13 described later to the first variable delay circuit DW2.

The first variable delay circuit DW2 is a digital delay circuit for delaying the second input data signal I_DQo input from the flip flop FF3 on the basis of the first control signal d1 from the first delay time controller 23 described later and then outputting the delayed second input data signal I_DQo to the flip flop FF4. For example, the first input data signal I_DQo input from the flip flop FF3 is delayed by only the first delay time Dt1 set in the first delay time controller 23 described later, and then output to the flip flop FF4.

In this embodiment, it is assumed that the same first delay time Dt1 is set in connection with each of plural SDRAM-1 to SDRAM-n. Specifically, the first delay time Dt1-1 is set in each of the first variable delay circuits DW0, DW1 and DW2 provided to the control circuit unit 15-1 shown in FIG. 5. Likewise, the first delay time Dt1-n is set in each of the first variable delay circuits DW0, DW1 and DW2 provided to the control circuit unit 15-n shown in FIG. 6.

Furthermore, with respect to reference character representing the first variable delay circuit, when it is necessary to specify one of the plural first variable delay circuits, the reference characters DW0, DW1, DW2, etc. are used. However, when any first variable delay circuit is indicated, the reference character DW is used.

In the following description, there is a case where the reference character DW-1 is used as the first variable delay circuit corresponding to SDRAM-1 of 1-ch (1-channel), and likewise there is also a case where the reference character DW-n is used as the first variable delay circuit corresponding to SDRAM-n of n-ch (n channel).

When the clock signal CK2 is input from the second clock signal generator 18, the flip flop FF4 outputs the second input data signal I_DQo input from the first variable delay circuit DW2 through the selector 21 to SDRAM. The DQ signal output controller 20 carries out the control of outputting the data signal DQ input from SDRAM to CPU 13 described later in the read operation. For example, in the control circuit unit 15-1, the DQ signal output controller 20 carries out the control of the data signal DQ-1[1] input from SDRAM-1 to CPU 13 described later as a third data signal O_DQe-1[1] or fourth data signal O_DQo-1[1] in connection with the plural DQ signal output controllers 20-1 to 20-k as shown in FIG. 5. Likewise, it carries out the control of outputting the data signal DQ-1[k] input from SDRAM-1 to CPU 13 described later as a third data signal O_DQe-1[k] or fourth data signal O_DQo-1[k].

Furthermore, in the control circuit unit 15-n, the DQ signal output controller 20 carries out the control of outputting the data signal DQ-n[1 ] input from SDRAM-n to CPU 13 described later as third data signal O_DQe-n[1] or fourth data signal O_DQo-n[1] in connection with the plural DQ signal output controllers 20-1 to 20-k as shown in FIG. 6. Likewise, it carries out the control of outputting the data signal DQ-n[k] input from SDRAM-n to CPU 13 described later as a third data signal O_DQe-n[k] or a fourth data signal O_DQ0-n[k].

With respect to reference character representing the third data signal, when it is necessary to specify one of the plural third data signals, the reference characters O_DQe-1[1] to O_DQe-1[k] and the reference characters O_DQe-n[1] to O_DQe-n[k] are used. However, when any third data signal is indicated, the reference character O_DQe is used. Furthermore, with respect to reference character representing the fourth data signal, when it is necessary to specify one of the plural fourth data signals, the reference characters O_DQo-1[1] to O_DQo-1[k] and O_DQo-n[1] to O_DQo-n[k] are used. However, when any fourth data signal is indicated, the reference character O_DQo is used.

In the case where the data signal is represented, when it is necessary to specify the third data signal and the fourth data signal, the reference characters O_DQe and O_DQe-1[1] to O_DQe-1[k] and O_DQe-n[1 ] to O_DQe-n[k] which represent the third data signals and O_{—DQo and O}_DQo-1[1 ] to O_DQo-1[k], O_DQo-n[1 ] to O_DQo-n[k] are used. However, when it is unnecessary to specify the third data signal and the fourth data signal, the reference characters DQ-1[1 ] to DQ-1[k], DQ-n[1 ] to DQ-n[k] which represent the data signals corresponding to SDRAM-1 to SDRAM-n are used. Furthermore, when any data signal is indicated, the reference character DQ is used. Furthermore, in the case where it is unnecessary to specify the third data signal and the fourth data signal, the reference characters DQ-1 to DQ-n may be used in place of the reference characters DQ-1[1] to DQ-1[k], DQ-n[1] to DQ-n[k] which represent the data signals corresponding to SDRAM-1 to SDRAM-n for convenience of description.

That is, the third data signals O_DQe-1[1 ] to O_DQe-1[k] corresponding to SDRAM-1 correspond to the third data signal O_DQe, the data signal DQ-1[1] to DQ-1[k], the data signal DQ-1 and the data signal DQ, and the third data signals O_DQe-n[1 ] to O_DQe-n[k] corresponding to SDRAM-n correspond to the third data signal O_DQe, the data signals DQ-n[1 ] to DQ-n[k], the data signal DQ-n and the data signal DQ. Furthermore, the fourth data signals O_DQo-1[1 ] to O_DQo-1[k] corresponding to SDRAM-1 correspond to the fourth data signal O_DQo, the data signals dQ-1[1 ] to DQ-1[k], the data DQ-1 and the data signal DQ, and the fourth data signals O_DQo-n[1] to O_DQo-n[k] corresponding to SDRAM-n correspond to the fourth data signal O_DQo, the data signals DQ-n[1] to DQ-n[k], the data DQ-n and the data signal DQ.

For example, the DQ signal output controller 20 is constructed by a flip flop FF5, a second variable delay circuit (second variable delay unit) DR1, a flip flop FF6, a flip flop FF7, a second variable delay circuit (second variable delay unit) DR2 and a flip flop FF8 as shown in FIGS. 5 and 6.

When a data strobe signal DQS is input from SDRAM, the flip flop FF5 outputs the third data signal O_DQe input from SDRAM to the second variable delay circuit DR1.

The second variable delay circuit DR1 is a digital delay circuit for delaying the third data signal O_DQe input from the flip flop FF5 on the basis of the second control signal d2 from the second delay time controller 24 described later, and then outputting the delayed third data signal O_DQe to the flip flop FF6. For example, the third data signal O_DQe input from the flip flop FF5 is delayed by only the second delay time set in the second delay time controller 24 described later, and then the delayed third data signal O_DQe is output to the flip flop FF6.

In this embodiment, the second delay time is set in each of the plural control circuit units 15-1 to 15-n. Specifically, the second delay time Dt2-1 is set in the second variable delay circuit DR1 of the control circuit unit 15-1, and likewise the second delay time Dt2-n is set in the second variable delay circuit DR1 of the control circuit unit 15-n.

With respect to reference character representing the second delay circuit, when it is necessary to specify one of the plural second delay times, the reference characters Dt2-1 to Dt2-n are used. However, when any second delay time is indicated, the reference character Dt2 is used.

When the clock signal CK1 is input from the first clock signal generator 14, the flip flop FF6 outputs the third data signal O_DQe input from the second variable delay circuit DR1 to CPU 13 described later. When the data strobe signal DQS is input from SDRAM, the flip flop FF7 outputs the fourth data signal O_DQo input from SDRAM to the second variable delay circuit DR2.

The second variable delay circuit DR2 is a digital delay circuit for delaying the fourth data signal O_DQo input from the flip flop FF7 on the basis of the second control signal d2 from the second delay time controller 24 described later and outputting the delayed fourth data signal O_DQo to a flip flop FF8. For example, the fourth data signal O_DQo input from the flip flop FF7 is delayed by only the second delay time Dt2 set in the second delay time controller 24 described later, and then output to the flip flop FF8.

In this embodiment, the same second delay time Dt2 is set in connection with each of the plural SDRAM-1 to SDRAM-n.

Specifically, a second delay time Dt2-1 is set in each of the second variable delay circuit DR1 and DR2 provided to the control circuit unit 15-1 shown in FIG. 5. Likewise, a second delay time Dt2-n is set in each of the second variable delay circuits DR1 and DR2 provided to the control circuit unit 15-n shown in FIG. 6.

With respect to reference character representing the second variable delay circuit, when it is necessary to specify one of the plural second variable delay circuits, the reference characters DR1, DR2, etc. are used. However, when any second variable delay circuit is indicated, the reference character DR is used.

In the following description, for convenience of description, the reference character DR-1 may be used as the second variable delay circuit corresponding to SDRAM-1 of 1-ch, and likewise the reference character DR-n may be used as the second variable delay circuit corresponding to SDRAM-n of n-ch.

When the clock signal CK1 is input from the first clock signal generator 14, the flip flop FF8 outputs the fourth data signal O_DQo input from the second variable delay circuit DR2 to CPU 13 described later.

The logical addition circuit OR is designed to output a response signal to CPU 13 described later on the basis of the third data signal O_DQe and the fourth data signal O_DQo when the write leveling function described later is used.

Specifically, in the case where the write leveling function described later is used, the logical addition circuit OR provided to the control circuit unit 15-1 outputs a response signal O_DQX-1 to CPU described later when any of plural third data signals O_DQe-1[1] to O_DQe-[k] corresponding to SDRAM-1 and plural fourth data signals O_DQo-1[1 ] to O_DQo-1[k] corresponding to SDRAM-1 is input as shown in FIG. 5.

Furthermore, in the case where the write leveling function described later is used, the logical addition circuit OR provided to the control circuit unit 15-n outputs a response signal O_DQX-n to CPU 13 described later when any of plural third data signals O_DQe-n[1] to O_DQe-n[k] corresponding to SDRAM-n and plural fourth data signals O_DQo-n[1] to O_DQo-n[k] corresponding to SDRAM-n is input as shown in FIG. 6.

With respect to reference character representing the response signal, when it is necessary to specify one of the plural response signals, the reference characters O_DQX-1 to O_DQX-n are used. However, when any response signal is indicated, the reference character O_DQX is used.

CPU 13 executes various kinds of numerical calculations, information processing, control of equipment, etc. in the information processing device 10, and it functions as a delay time controller 22 in this embodiment. Furthermore, CPU 13 has MAC (Media Access Control; not shown), and it inputs/outputs various kinds of signals (data signal DQ, clock signal CLK, response signal DQX, etc.) through this MAC.

The delay time controller 22 outputs a control signal for setting the delay time to the first variable delay circuit DW and the second variable delay circuit DR provided to each of the control circuit units 15-1 to 15-n, and it is equipped with the first delay time controller 23 and the second delay time controller 24 as shown in FIG. 4.

The first delay time controller 23 controls the first variable delay circuit DW provided to each of the control circuit units 15-1 to 15-n to execute delay of the first delay time Dt1 by using the write leveling function, and it outputs a first control signal d1 for setting the first delay time Dt1. Furthermore, by using the write leveling function, the first delay time controller 23 sets the respective first delay times Dt1-1 to Dt1-n of the data strobe signals DQS-1 to DQS-n which are output to the plural SDRAM-1 to SDRAM-n respectively in the write operation.

Here, the write leveling function is a function of performing adjustment (correction) so that the respective data strobe signals DQS-1 to DQS-n are input to the plural SDRAM-1 to SDRAM-n substantially at the same time as the clock signal CK1. This adjustment (correction) is implemented by setting the respective first delay times Dt1-1 to Dt1-n of the data strobe signals DQS-1 to DQS-n output to the plural SDRAM-1 to SDRAM-n wired to the clock signal line by the daisy chain connection are set on the basis of the respective data signals DQ-1 to DQ-n output from SDRAM-1 to SDRAM-n.

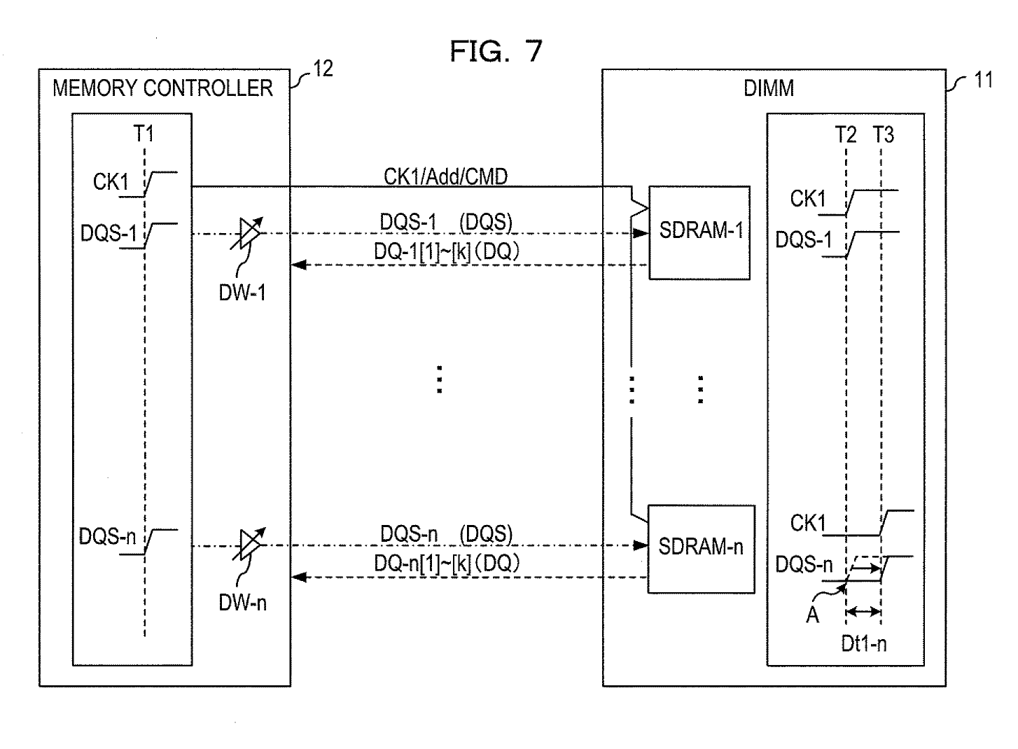

FIG. 7 is a diagram showing the write leveling function in the first delay time controller of the information processing device as the embodiment.

A case where the first delay times Dt1-1 to Dt1-n corresponding to the plural SDRAM-1 to SDRAM-n are set by using the write leveling function in the first delay time controller 23 will be described by using an example in which the first delay time Dt1-1 corresponding to SDRAM-1 of 1-ch and the first delay time Dt1-n corresponding to SDRAM-n of n-ch as shown in FIG. 7 are set. Furthermore, each SDRAM (SDRAM-1, SDRAM-n in the example of FIG. 7) outputs the data signal DQ (DQ-1[1] to [k], DQ-n[1] to [k] in the example of FIG. 7) to the memory controller 12 when the clock signal CK1 and the data strobe signal DQS (DQS-1, DQS-n in the example of FIG. 7) is input substantially at the same time.

First, the memory controller 12 outputs the clock signal CK1 to each SDRAM (SDRAM-1, SDRAM-n in the example of FIG. 7) and simultaneously or substantially simultaneously with this output, the memory controller 12 outputs each data strobe signal DQS (DQS-1, DQS-n in the example of FIG. 7) to each SDRAM (SDRAM-1, SDRAM-n in the example of FIG. 7) (see the time “T1” of FIG. 7).

For example, before the first delay time Dt1 is adjusted by the write leveling function, the clock signal CK1 and the data strobe signal DQS-1 are input to SDRAM-1 of 1-ch substantially at the same time (see the time “T2” of FIG. 7) and the clock signal CK1 is input to SDRAM-n of n-ch with a time delay of only the time Dt1-n (see the time “T3” of FIG. 7) after the data strobe signal DQS-n is input ((see the time “T2” of FIG. 7 and the point “A”) as shown in FIG. 7.

In this case, with respect to SDRAM-1 of 1-ch, the clock signal CK1 and the data strobe signal DQS-1 are input substantially at the same time, and thus any one of the data signals DQ-1[1] to [k] from SDRAM-1 of 1-ch is input to the logical addition circuit OR-1. Accordingly, the first delay time controller 23 (not shown in FIG. 7) detects that the logical addition circuit OR-1 outputs the response signal O_DQX-1, whereby the first delay time Dt-1 corresponding to the data strobe signal DQS-1 is not set in the first variable delay circuit DW-1.

On the other hand, with respect to SDRAM-n of n-ch, the first delay time Dt1-n corresponding to the data strobe signal DQS-n is set in the first variable delay circuit DW-n (see the time “T3” of FIG. 7) in conformity with the clock signal CK1 which is input while delayed by only the time Dt1-n after the clock signal CK1 is input to SDRAM-1 of 1-ch (see the time “T2” of FIG. 7).

That is, in the SDRAM-n of n-ch, the first delay time controller 23 (not shown in FIG. 7) gradually extends the delay time of the first variable delay circuit DW-n until the clock signal CK1 and the data strobe signal DQS-n are input substantially at the same time, thereby setting the time from the input of any one of the data signals DQ-n[1 ] to [k] from SDRAM-n into the logical addition circuit OR-n until the output of the response signal O_DQX-n from the logical addition circuit OR-n as the first delay time Dt1-n into the first variable delay circuit DW-n.

Accordingly, the first delay time controller 23 adjusts the input timing of the clock signal CK1 and the data strobe signal DQS for the respective SDRAM-1 to SDRAM-n by setting the first delay time Dt1-n into the first variable delay circuit DW-n.

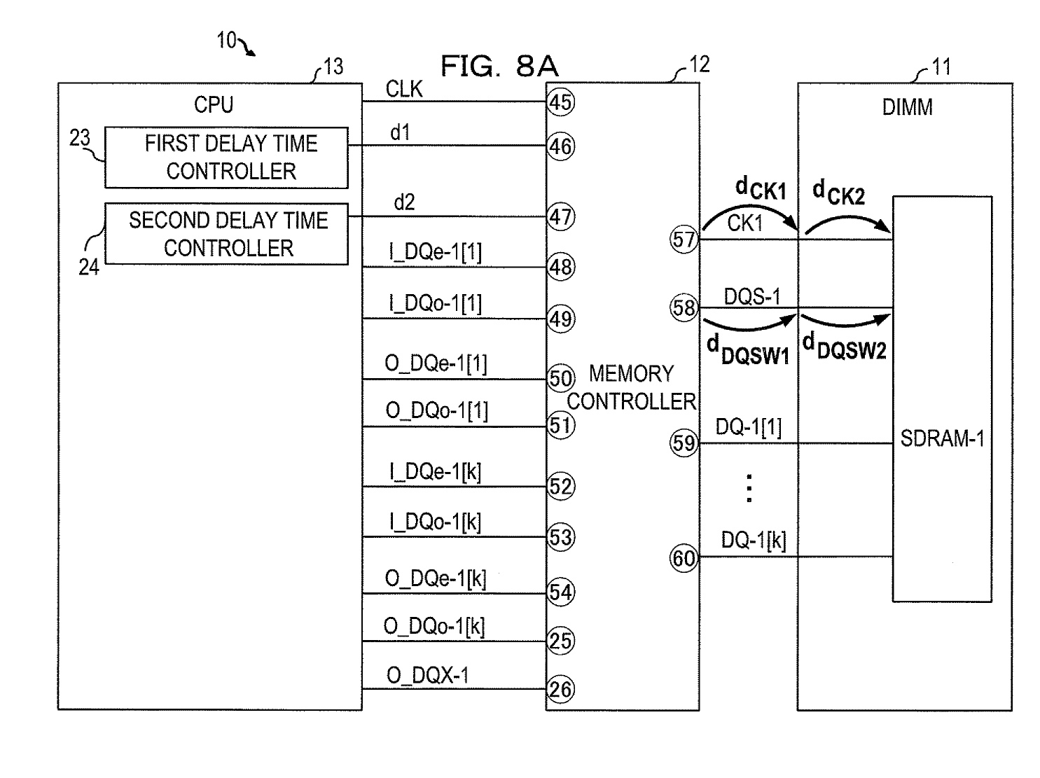

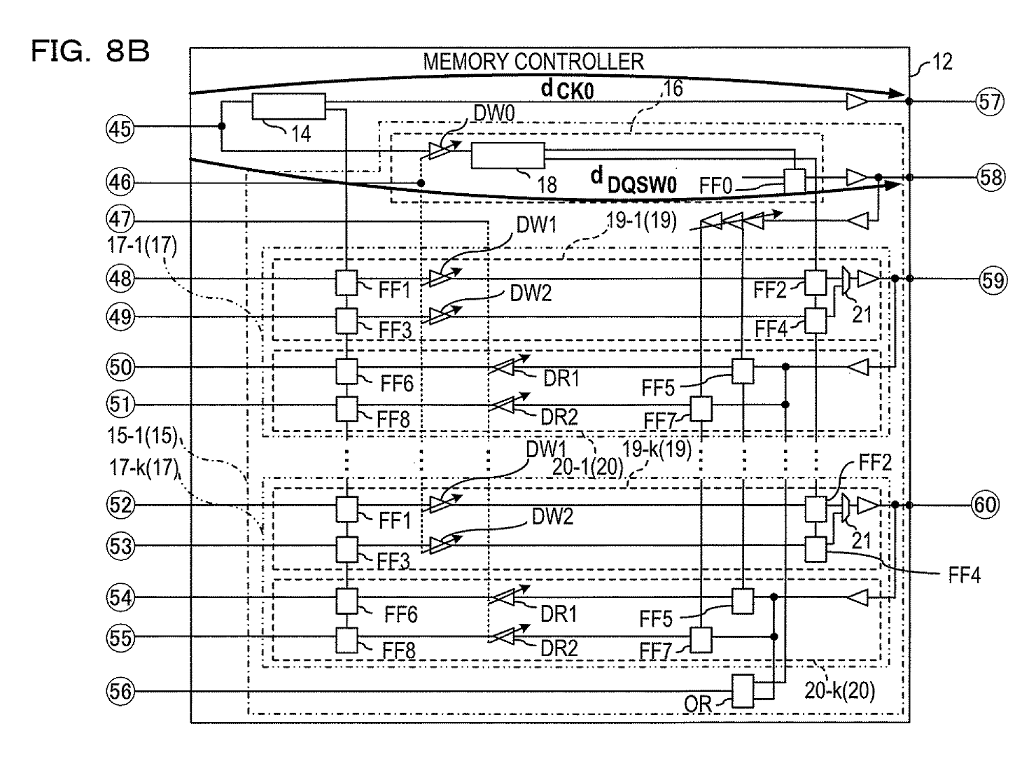

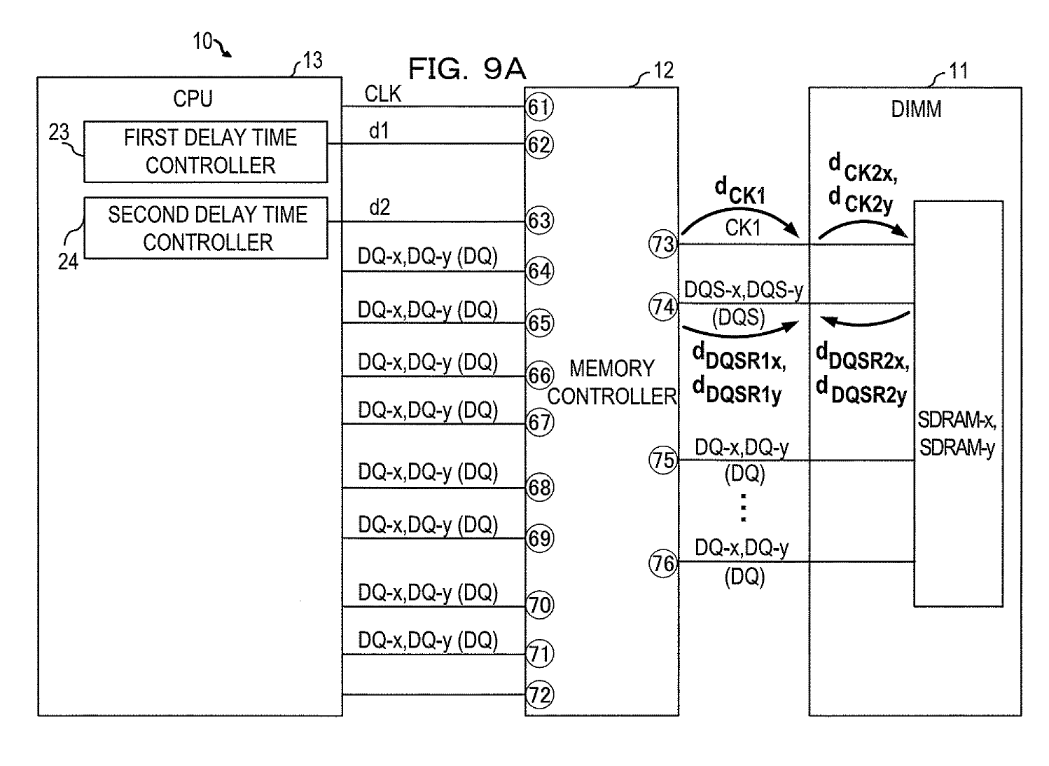

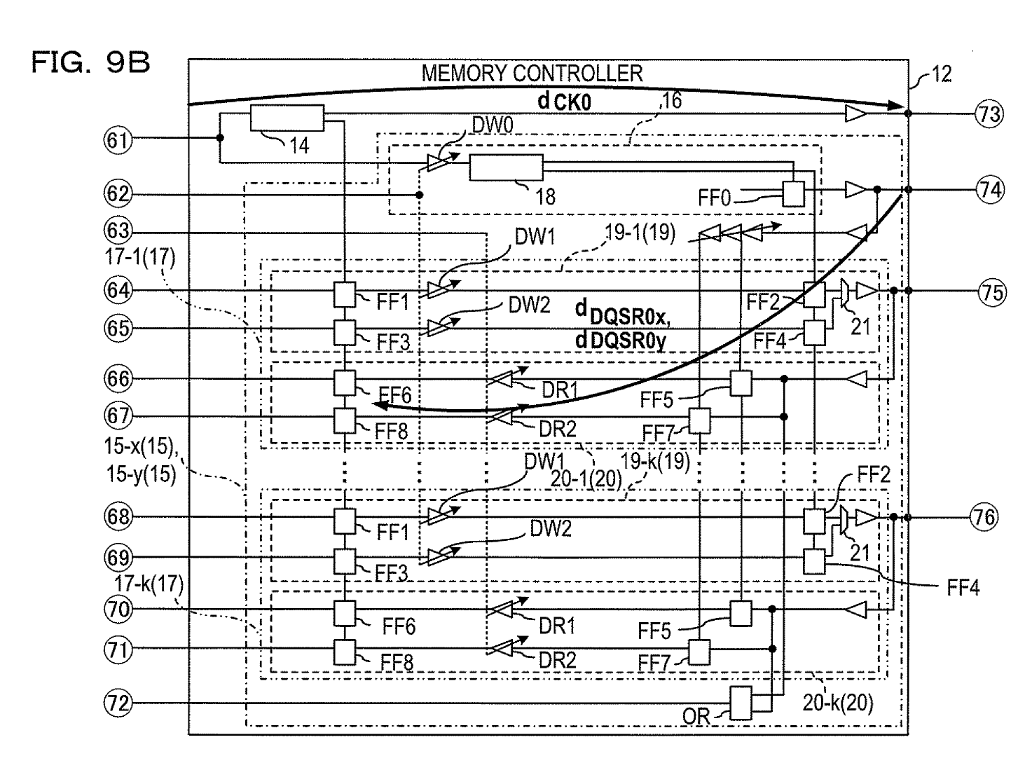

FIGS. 8 and 9 are diagrams showing a calculating calculation of calculating the first delay time in the first delay time controller of the information processing device according to the embodiment.

The following calculation equation (equation 1) is satisfied at the time point when the adjustment of each of the first delay time Dt1-1 to Dt1-n is completed.

dCK0+dCK1+dCK2=dDQSW0+dDQSW1+dDQSW2 (equation 1)

As shown in FIG. 8, dCK0 represents the time from the input of the clock signal CLK until the output of the clock signal CK1 in the memory controller 12, and dCK1 represents the time from the output of the clock signal CK1 from the memory controller 12 until the input of the clock signal CK1 to DIMM 11. Furthermore, dCK2 represents the time from the input of the clock signal CK1 to DIMM 11 until the input of the clock signal CK1 to each of SDRAM-1 to SDRAM-n. In FIG. 8, the clock signal CK1 represents the time from the input of the clock signal CK1 to DIMM 11 until the input of the clock signal CK1 to SDRAM-1.

Furthermore, dDQSW0 represents the time from the input of the clock signal CLK to the output of each of the data strobe signals DQS-1 to DQS-n in the memory controller 12, and it represents the time from the input of the clock signal CLK to the memory controller 12 until the output of the data strobe signal DQS-1 in FIG. 8.

Furthermore, dDQSW1 represents the time from the output of each of the data strobe signals DQS-1 to DQS-n from the memory controller 12 until the input thereof to DIMM 11, and it represents the time from the output of the data strobe signal DQS-1 from the memory controller 12 until the input thereof to DIMM 11 in FIG. 8.

Still furthermore, dDQSW2 represents the time from the input of each of the data strobe signals DQS-1 to DQS-n to DIMM 11 until the input thereof to each of SDRAM-1 to SDRAM-n, and it represents the time from the input of the data strobe signal DQS-1 to DIMM 11 until the input thereof to SDRAM-1 in FIG. 8.

The connection wires of the memory controller 12 and DIMM 11 are formed to be equal to each other in length, and thus dCK1=dDQSW1 is satisfied in the above equation (1). By transforming the equation (1), equations such as equation (2-1), equation (2-2) are obtained.

dCK0+dCK2=dDQSW0+dDQSW2 equation (2-1)

dCK2=dDQSW0−dCK0+dDQSW2 equation (2-2)

When (dDQSW0−dCK0) is set as the delay time Delay(W)n in the write operation in SDRAM-n of n-ch in the above equation (2-2), the following equation (2-3) is obtained.

dCK2=Delay(W)n+dDQSW2 equation (2-3)

Accordingly, the respective first delay times Dt1-1 to Dt1-n of SDRAM-1 to SDRAM-n are set so that the delay time is successively longer from SDRAM-1 of 1-ch to SDRAM-n of n-ch. The first delay time controller 23 outputs the respective first control signals d1 to the first variable delay circuits DW-1 to DW-n so as to obtain the respective set first delay times Dt1-1 to Dt1-n, and the respective first variable delay circuits DW-1 to DW-n delay the respective data strobe signals DQS-1 to DQS-n by only the first delay times Dt1-1 to Dt1-n respectively on the basis of these first control signals d1.

That is, in the write operation, the first variable delay circuit DW delays the data strobe signal DQS to be output to SDRAM by only the first delay time Dt1 which is set by using the write leveling function.

The second delay time controller 24 controls the second variable delay circuits DR provided to the control circuit units 15-1 to 15-n on the basis of the respective first delay times Dt1-1 to Dt1-n set by the first delay time controller 23 so that the second delay times Dt2 thereof are delayed, and outputs the second control signals d2 for setting the second delay times Dt2. In this embodiment, the second delay time controller 24 calculates/sets the respective second delay times Dt2 of the data signals DQ-1 to DQ-n input from the plural SDRAM-1 to SDRAM-n in the read operation on the basis of the first delay times Dt1-1 to Dt1-n set by the first delay time controller 23.

Specifically, the second delay time controller 24 sets the delay time Delay(R) of each of the data signals DQ-1 to DQ-n input from each of SDRAM-1 to SDRAM-n. For example, as shown in FIG. 9, with respect to SDRAM-x of x(x represents a natural number)-ch and SDRAM-y of y(y represents a natural number)-ch, each lapse time Pass(R)x, Pass(R)y from the input of the clock signal CLK to the memory controller 12 until the output of each data signal DQ-x, DQ-y from the memory controller 12 to CPU 13 are represented by the following equations (3-1) and (3-2).

Pass(R)x=dCK0+dCK1+dCK2x+dDQSR2x+dDQSR1x+dDQSR0x equation (3-1)

Pass(R)y=dCK0+dCK1+dCK2y+dDQSR2y+dDQSR1y+dDQSR0y equation (3-2)

As shown in FIG. 9, dCK0 represents the time from the input of the clock signal CLK until the output of the clock signal CK1 in the memory controller 12, and dCK1 represents the time from the output of the clock signal CK1 from the memory controller 12 until the input of the clock signal CK1 to DIMM 11 as in the case of the foregoing description. Furthermore, dCK2x represents the time from the input of the clock signal CK1 to DIMM 11 until the input of the clock signal CK1 to SDRAM-x of x-ch, and dDQSR2x represents the time from the output of the data strobe signal DQS-x of x-ch from SDRAM-x of x-ch until the output of the data strobe signal DQS-x of x-ch from DIMM 11. Furthermore, dDQSR1x represents the time from the output of the data strobe signal DQS-x of x-ch from DIMM 11 until the input thereof to the memory controller 12, and dDQSR0x represents the time from the input of the data strobe signal DQS-x of x-ch to the memory controller 12 until the input to data signal DQ-x to the flip flop FF6 or the flip flop FF8.

Furthermore, as shown in FIG. 9, dCK2y represents the time from the input of the clock signal CK1 to DIMM 11 until the input thereof to SDRAM-y of y-ch, and dDQSR2y represents the time from the output of the data strobe signal DQS-y of y-ch from SDRAM-y of y-ch until the output thereof from DIMM 11. Furthermore, dDQSR1 y represents the time from the output of the data strobe signal DQS-y of y-ch from DIMM 11 until the input thereof to the memory controller 12, and dDQSR0y represents the time from the input of the data strobe signal DQS-y of y-ch to the memory controller 12 until the input of the data signal DQ-y to the flip flop FF6 or the flip flop FF8. Here, in order to make the elapsed time Pass(R)x at x-ch and the elapsed time Pass(R)y at y-ch equal to each other, the following equation (3-3) is required to be satisfied.

dCK0+dCK1+dCK2x+dDQSR2x+dDQSR1x+dDQSR0x=dCK0+dCK1+dCK2y+dDQSR2y+dDQSR1y+dDQSR0y equation (3-3)

In the equation (3-3), the connection wires between the memory controller 12 and DIMM 11 are isometrically formed, and thus it can be established that dDQSR2x=dDQSR2y and dDQSR1x=dDQSR1y. Accordingly, by transforming the equation (3-3), the following equation (3-4) is obtained.

dCK2x+dDQSR0x=dCK2y+dDQSR0y equation (3-4)

Here, by setting dDQSR0x=Delay(R)x+a and dDQSW2x=dDQSW2y and substituting these equations into the equation (2-3), the following equation (3-5) is obtained.

Delay(W)x+Delay(R)x=Delay(W)y+Delay(R)y equation (3-5)

By generalizing the equation (3-5), the following equation (3-6) is obtained.

Delay(R)n=max(Delay(W))−Delay(W)n equation (3-6)

The thus-calculated delay time is given to Delay(R)n. That is, the second delay time Dt2 of the data signal DQ input from SDRAM can be calculated by utilizing the first delay time Dt1 set in the write leveling operation.

Accordingly, in the second delay time controller 24, by using the equation (3-5), the second delay time Dt2-x of one SDRAM-x is set so that the sum of the first delay time Dt1-x corresponding to SDRAM-x concerned and the second delay time Dt2-x is equal to a preset value.

Furthermore, in the second delay time controller 24, by using the equation (3-5), the second delay time Dt2-x corresponding to one SDRAM-x is set so that the sum of the first delay time Dt1-x corresponding to SDRAM-x concerned and the second delay time Dt2-x is equal to the sum of the first delay time Dt1-y corresponding to another SDRAM-y and the second delay time Dt2-y.

Still furthermore, in the second delay time controller 24, by using the equation (3-6), the second delay time Dt2-x corresponding to one SDRAM-x corresponds to the difference between the first delay time Dt1-x corresponding to SDRAM-x and the maximum delay time Dt1-n of the plural first delay times Dt1-1 to Dt1-n corresponding to plural SDRAM-1 to SDRAM-n.

Accordingly, the second delay times Dt2-1 to Dt2-n corresponding to SDRAM-1 to SDRAM-n are set so that the delay time is successively shortened from SDRAM-1 of 1-ch to SDRAM-n of n-ch.

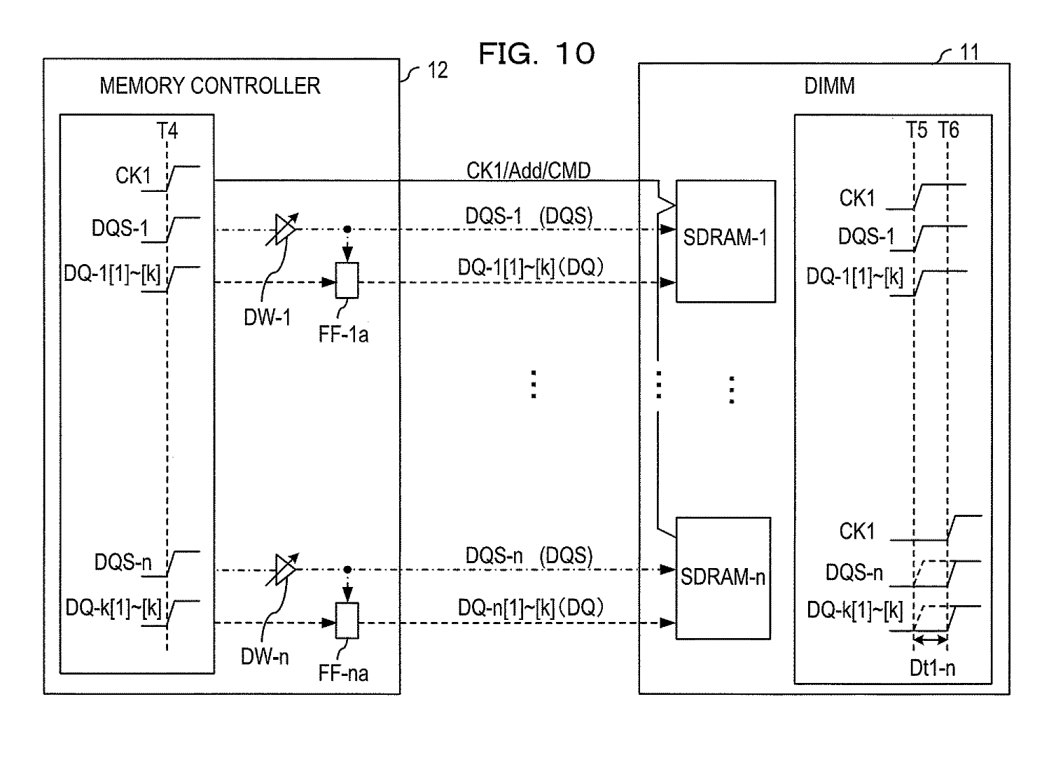

The second delay time controller 24 outputs the second control signal d2 to each of the second variable delay circuits DR-1 to DR-n so as to obtain the respective set second delay times Dt2-1 to Dt2-n, and the second variable delay circuits DR-1 to DR-n delay the respective data signals DQ-1 to DQ-n by only the second delay times Dt2-1 to Dt2-n on the basis of these second control signals d2. That is, the second variable delay circuit DR delays the data signal DQ input from SDRAM by only the second delay time Dt2 set on the basis of the first delay time Dt1 in the read operation. A case where the write operation is carried out by using the first variable delay circuit DW in the above information processing device 10 according to the embodiment will be described with reference to FIG. 10.

In the following description, for convenience of description, it is assumed that the writing operation is carried out on SDRAM-1 of 1-ch and SDRAM-n of n-ch.

In the following description, each of the flip flops FF2, FF4 corresponding to SDRAM-1 of 1-ch is represented by reference character FF-1a in place of FF2, FF4, and each of the flip flops FF2, FF4 corresponding to SDRAM-n of n-ch is represented by reference character FF-na in place of FF2, FF4.

The first delay time controller 23 sets the respective first delay times Dt1-1 to Dt1-n corresponding to plural SDRAM-1 to SDRAM-n by using the write leveling function. Furthermore, the first control signals d1 corresponding to the respective set first delay times Dt1-1 to Dt1-n are output to the corresponding first variable delay circuits DW-1 to DW-n respectively (first delay time control operation).

The first delay times Dt1-1 to Dt1-n are set in the first variable delay circuits DW-1 to DW-n, and then the following write operation is executed.

The memory controller 12 outputs the clock signal CK1 to each SDRAM (SDRAM-1, SDRAM-n in the example shown in FIG. 10), and also it generates each data strobe signal (DQS-1, DQS-n in the example shown in FIG. 10) substantially simultaneously with the output of the clock signal CK1 and outputs the generated data strobe signal to each first variable delay circuit (DW-1, DW-n in the example shown in FIG. 10) (see the time “T4” of FIG. 10).

Here, in the case of FIG. 10, the first variable delay circuit DW-1 outputs the input data strobe signal DQS-1 to SDRAM-1 and the flip flop FF-1a without delaying the data strobe signal DOS-1, and the first variable delay circuit DW-n outputs the input data strobe signal DQS-n to the SDRAM-n and the flip flop FF-na while delaying the data strobe signal DQS-n by only the first delay time Dt1-n.

Furthermore, the memory controller 12 outputs the data signals DQ-1[1 ] to [k] corresponding to SDRAM-1 through the first variable delay circuit (not shown; having the same construction as the first variable delay circuit DW-1) to the flip flop FF-1a substantially at the same time as the data strobe signal DQS-1, and also outputs the data signals DQ-n[1] to [k] corresponding to SDRAM-n through the first variable delay circuit (not shown; having the same construction as the first variable delay circuit DW-n) to the flip flop FF-na substantially at the same time as the data strobe signal DQS-n.

When the data strobe signal DQS-1 is input, the flip flop FF-1 a outputs the data signals DQ-1[1] to [k] to SDRAM-1. Likewise, when the data strobe signal DQS-n is input, the flip flop FF-na outputs the data signals DQ-n[1] to [k] to SDRAM-n.

The data strobe signal DQS-1 and the data signals DQ-1[1] to [k] are input to SDRAM-1 substantially at the same time as the clock signal CK1 (see the time “T5” of FIG. 10), and the data strobe signal DQS-n and the data signals DQ-n[1 ] to [k] are delayed by only the first delay time Dt1-n after the clock signal CK1 is input to SDRAM-1 (see the time “T5” of FIG. 10), and input to SDRAM-n substantially at the same time as the clock signal CK1 (see the time “T6” of FIG. 10).

Accordingly, the data strobe signal DQS and the data signal DQ are input to each of SDRAM-1 to SDRAM-n substantially at the same time as the clock signal CK1, and the write operation is executed.

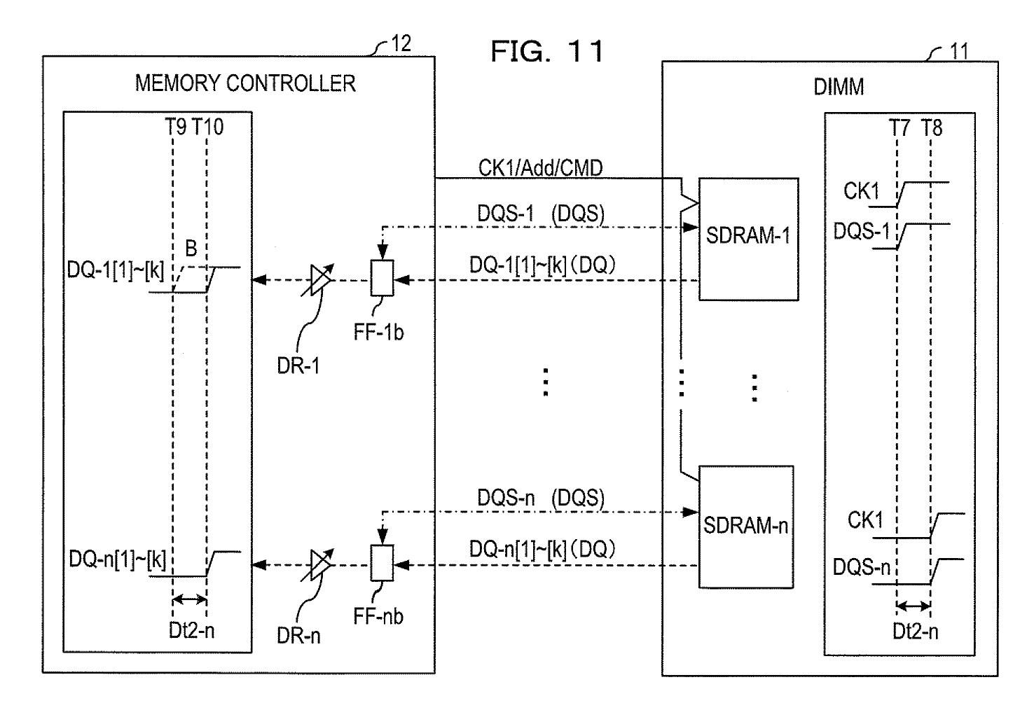

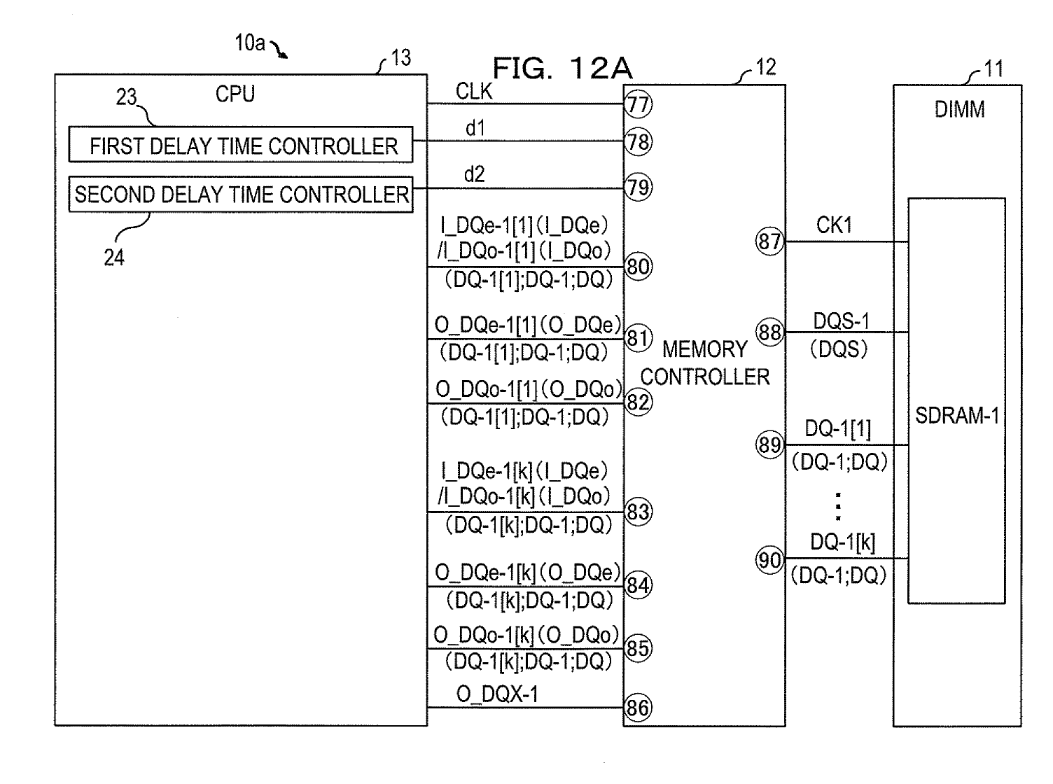

Next, a case where the read operation is executed by using the second variable delay circuit DR in the above information processing device 10 according to the embodiment will be described with reference to FIG. 11.

In the following description, for convenience of description, it is assumed that the read operation is executed on SDRAM-1 of 1-ch and SDRAM-n of n-ch.

Furthermore, in the following description, for convenience of description, the respective flip flops corresponding to SDRAM-1 of 1-ch are represented by reference character FF-1b in place of FF5, FF7, and the respective flip flops corresponding to SDRAM-n of n-ch are represented by reference character FF-nb in place of FF5, FF7.

The second delay time controller 24 sets the second delay times Dt2-1 to Dt2-n corresponding to plural SDRAM-1 to SDRAM-n on the basis of the respective first delay times Dt1-1 to Dt1-n corresponding to plural SDRAM-1 to SDRAM-n, and outputs the second control signals d2 corresponding to these set second delay times Dt2-1 to Dt2-n to the corresponding second variable delay circuits DR-1 to DR-n (second delay time control operation).

The second delay times Dt2-1 to Dt2-n are set in the second variable delay circuits DR-1 to DR-n respectively, and then the following read operation is carried out.

The memory controller 12 outputs the clock signal CK1 to each SDRAM (SDRAM-1, SDRAM-n in the example shown in FIG. 11) (see the time “T7” of FIG. 11). In this case, the clock signal lines of the SDRAM-1 to SDRAM-n are wired by daisy chain connection, and thus the clock signal CK1 is successively input from SDRAM-1 to SDRAM-n.

Therefore, the clock signal CK1 is input to the SDRAM-n while delayed by only the second delay time Dt2-n from the input of the clock signal CK1 to SDRAM-1 (see the time “T8” of FIG. 11).

In the case shown in FIG. 11, when the clock signal CK1 is input, SDRAM-1 outputs the data strobe signal DQS-1 and the data signals DQ-1[1] to [k] to the flip flop F-1b in the memory controller 12 (see the time “T7” of FIG. 11). Likewise, when the clock signal CK1 is input to SDRAM-n with being delayed by only the second delay time Dt2-n after it is input to SDRAM-1, SDRAM-n outputs the data strobe signal DQS-n and the data signals DQ-n[1] to [k] to the flip flop F-1nb in the memory controller 12 (see the time “T8” of FIG. 11).

When the data strobe signal DQS-1 is input, the flip flop F-1b outputs the data signals DQ-1[1] to [k] to the second variable delay circuit DR-1. Likewise, when the data strobe signal DQS-n is input, the flip flop F-nb outputs the data signals DQ-n[1] to [k] to the second variable delay circuit DR-n.

The second variable delay circuit DR-n outputs the input data signals DQ-n[1] to [k] to CPU 13 (not shown in FIG. 11) without delaying the input data signals concerned, and the second variable delay circuit DR-1 delays the input data signals DQ-1[1] to [k] by only the second delay time dt2-n and then output the delayed data signals to CPU 13 (see the time “T9”, the time “T10” and a dashed line portion “B” of FIG. 11).

Accordingly, the respective data signals DQ corresponding to SDRAM-1 to SDRAM-n are input to CPU 13 substantially at the same time, and the read operation is executed.

As described above, according to the information processing device 10 as the embodiment, on the basis of the first delay time Dt1 set by using the write leveling function, the second delay time Dt2 of the data signal DQ input from SDRAM in the read operation is set to plural SDRAM-1 to SDRAM-n to which the clock signal line is wired by daisy chain connection. Accordingly, the input times of the data signals DQ output from plural SDRAM-1 to SDRAM-n to which the clock signal line is wired by daisy chain connection can be matched with one another. Accordingly, when the read operation is controlled, a disadvantage caused by propagation delay of the data signal DQ can be prevented.

Furthermore, by providing the second variable delay circuit DR for introducing a delay of only the second delay time Dt2 on the basis of the first delay time Dt1 set by using the write leveling function, a memory interface which can match the input times of the data signals DQ output from plural SDRAM-1 to SDRAM-n to which the clock signal line is wired by daisy chain connection can be easily implemented without providing any special mechanism such as FIFO or the like.

Still furthermore, the data signal lines through which the memory controller 12 and DIMM 11 are connected to each other are formed isometrically, whereby the calculation equation of the second delay time Dt2 can be simplified and the second delay time Dt2 of the data signal DQ input from SDRAM in the read operation can be easily obtained.

The sum of the first delay time Dt1 and the second delay time Dt2 corresponding to one SDRAM is set to be equal to a preset value, and the sum of the first delay time Dt1 and the second delay time Dt2 corresponding to one SDRAM is set to be equal to the sum of the first delay time Dt1 and the second delay time Dt2 of another SDRAM. Accordingly, the setting reference for the second delay time Dt2 can be clarified on the basis of the first delay time Dt1 set by using the write leveling function, and the second delay times Dt2 for plural SDRAMs can be easily obtained.

Furthermore, the second delay time Dt2 corresponding to one SDRAM is set to the difference between the first delay time Dt1 corresponding to the SDRAM concerned and the maximum delay time Dt1-n of the plural first delay times Dt1-1 to Dt1-n corresponding to plural SDRAM-1 to SDRAM-n. Accordingly, the calculation equation of the second delay time Dt2 can be generalized, and the second delay times Dt2 for the plural SDRAM-1 to SDRAM-n can be easily obtained.

### Description of Modification of First Embodiment

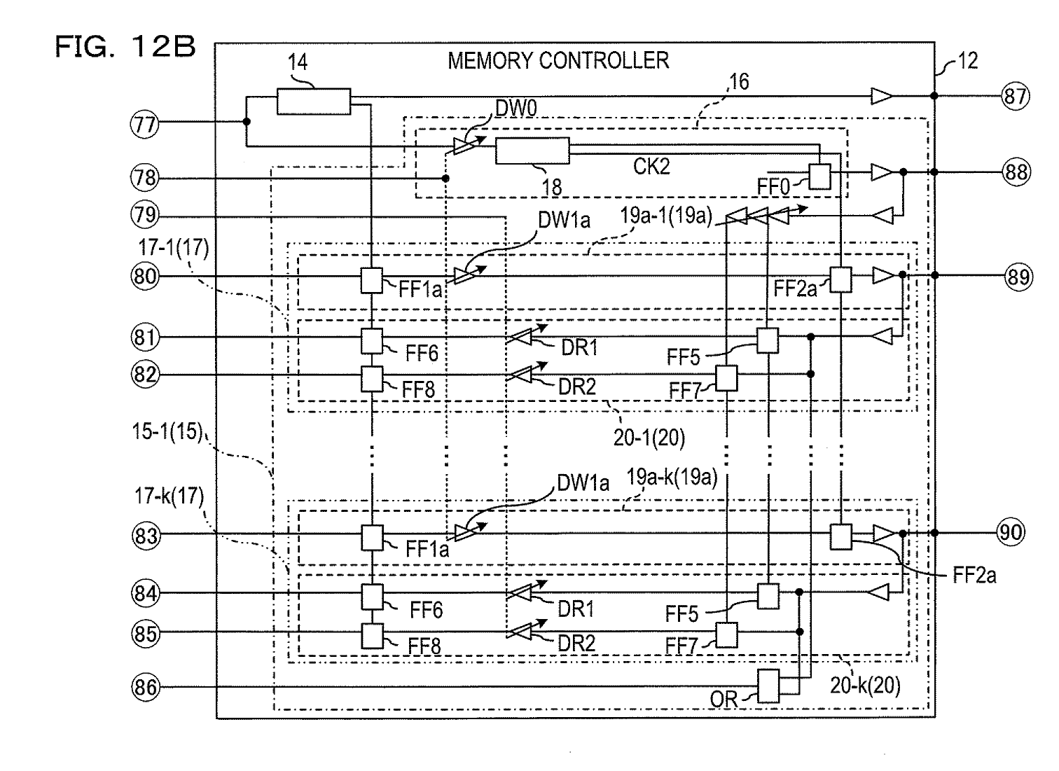

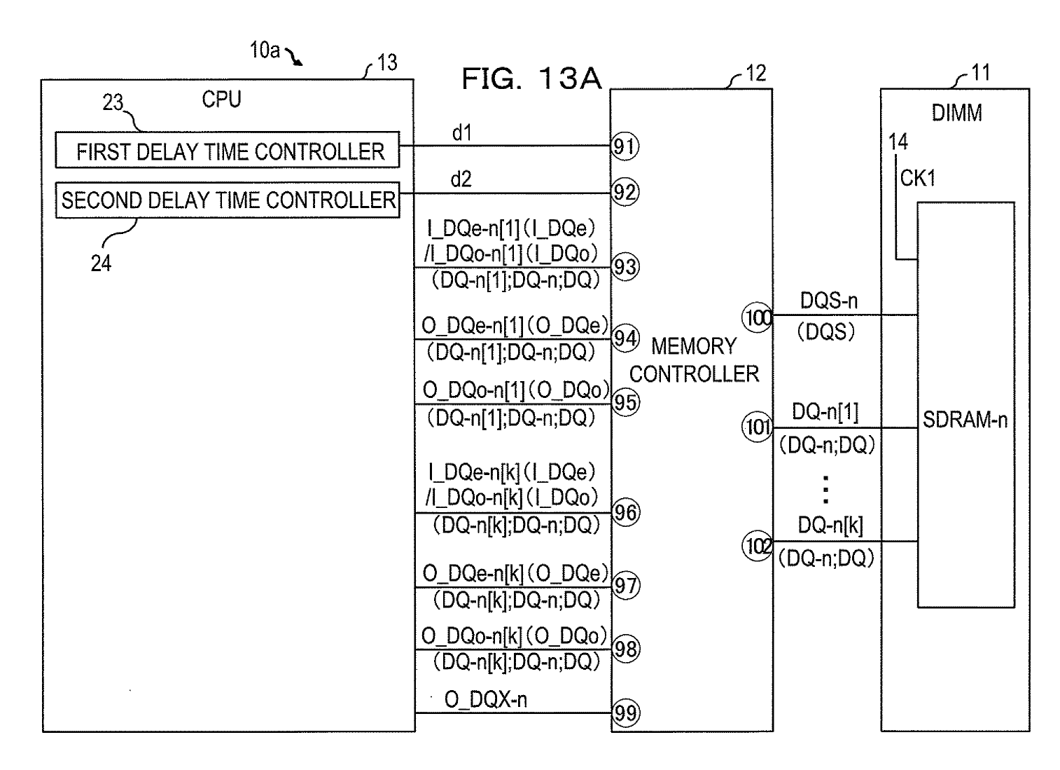

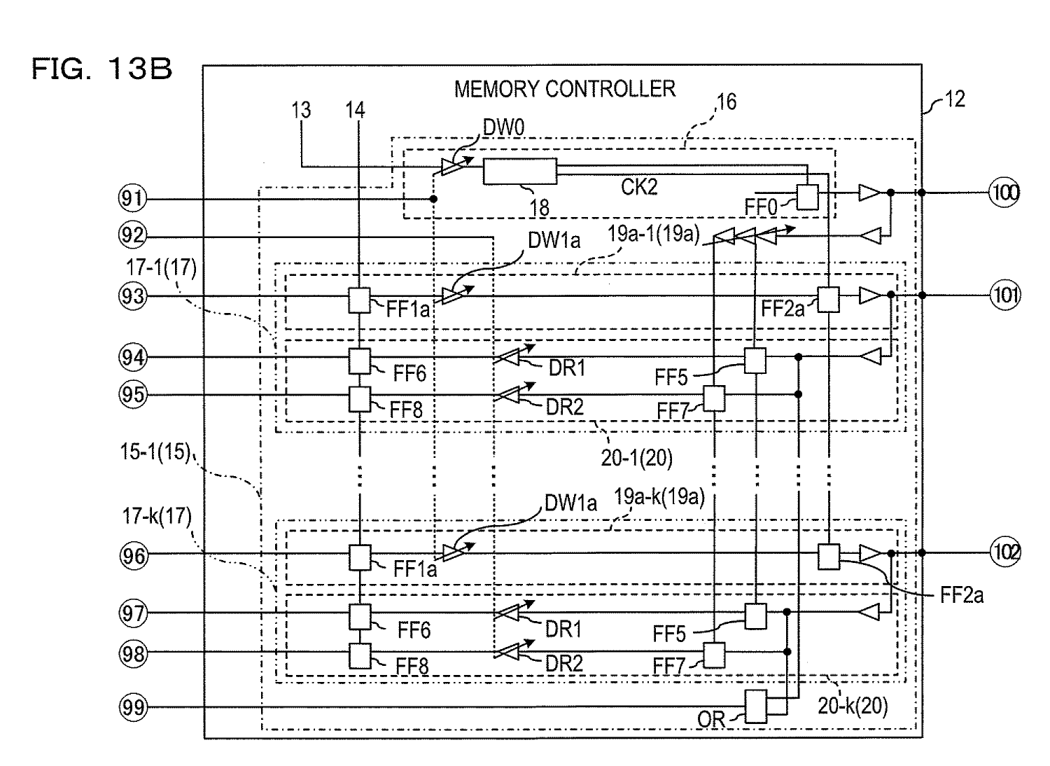

Next, a modification of the information processing device 10 according to the embodiment will be described with reference to FIGS. 12 and 13.

FIG. 12 is a circuit diagram showing a part corresponding to SDRAM-1 of the memory controller in the information processing device as a modification of the embodiment, and FIG. 13 is a circuit diagram showing a part corresponding to SDRAM-n.

As shown in FIGS. 12 and 13, the information processing device 10a as a modification of the embodiment is equipped with DQ signal input controllers 19a-1 to 19a-k are provided in place of the DQ signal input controllers 19-1 to 19-k of the respective control circuit units 15-1 to 15-n of the embodiment, and the other parts are designed to have the same construction as the information processing device 10 of the embodiment.

In the figures, the reference numerals same as the previously mentioned reference numerals represent the same or substantially the same parts, and thus the description thereof is omitted.

With respect to reference character representing the DQ signal input controller in the modification of the embodiment, when it is required to specify one of the plural DQ signal input controllers, reference characters 19a-1 to 19a-k are used. However, when any DQ signal input controller is indicated, reference character 19a is used.

The DQ signal input controller 19a in the modification of the embodiment carries out the control of outputting a first data signal I_DQe and a second data signal I_DQo input from CPU 13 to SDRAM in the write operation as in the case of the DQ signal input controller 19 of the above embodiment. Unlike the DQ signal input controller 19 of the above-described embodiment, the DQ signal input controller 19a of this modification multiplexes the first data signal I_DQe and the second data signal I_DQo and then outputs the multiplexed signal to SDRAM.

A method of multiplexing the first data signal I_DQe and the second data signal I_DQo and then outputting the multiplexed signal to SDRAM is a well-known technique, and thus the detailed description thereof is omitted.

Accordingly, the DQ signal input controller 19a in the modification of the embodiment is equipped with a flip flop FF1a, a first variable delay circuit (first variable delay unit) DW1a and a flip flop FF2a as shown in FIGS. 12 and 13, for example.

When the clock signal CK1 is input from the first clock signal generator 14, the flip flop FF1a outputs the first data signal I_DQe or the second data signal I_DQo input from CPU 13 to the first variable delay circuit DW1a.

The first variable delay circuit DW1a is a digital delay circuit for delaying the first data signal I_DQe or the second data signal I_DQo input from the flip flop FF1a on the basis of the first control signal d1 from the first delay time controller 23 and then outputting the delayed data signal to the flip flop FF2a. For example, the first data signal I_DQe or the second data signal I_DQo input from the flip flop FF1a is delayed by only the first delay time Dt1-1 set by the first delay time controller 23, and then output to the flip flop FF2a.

When the clock signal CK2 from the second clock signal generator 18 is input, the flip flop FF2a outputs the first data signal I_DQe or the second data signal L_DQo input from the first variable delay circuit DW1a to SDRAM.

As described, the same action and effect as the above-described embodiment can be also obtained by the information processing device 10a as the modification of the embodiment.

### Description of Second Embodiment

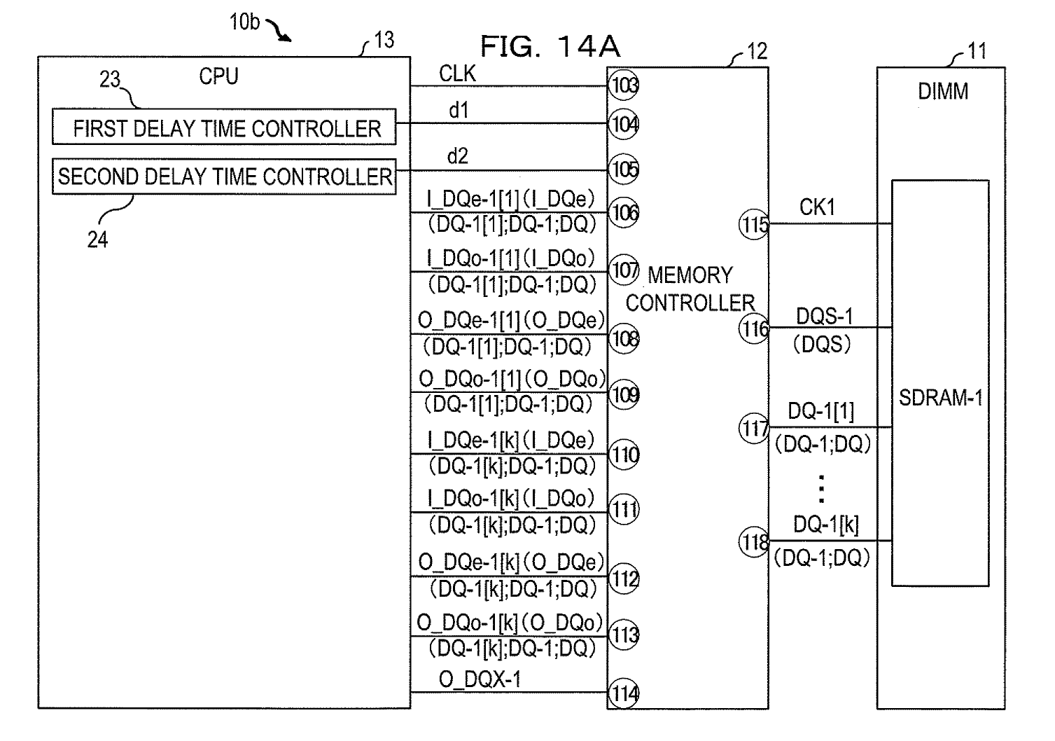

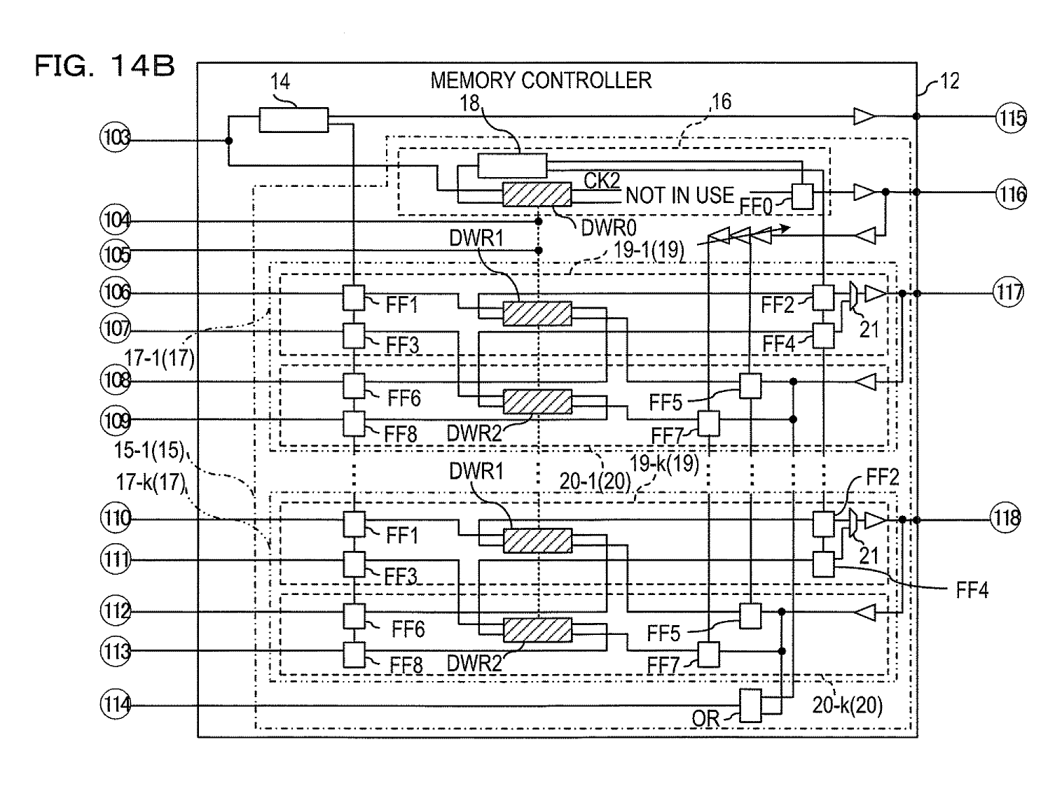

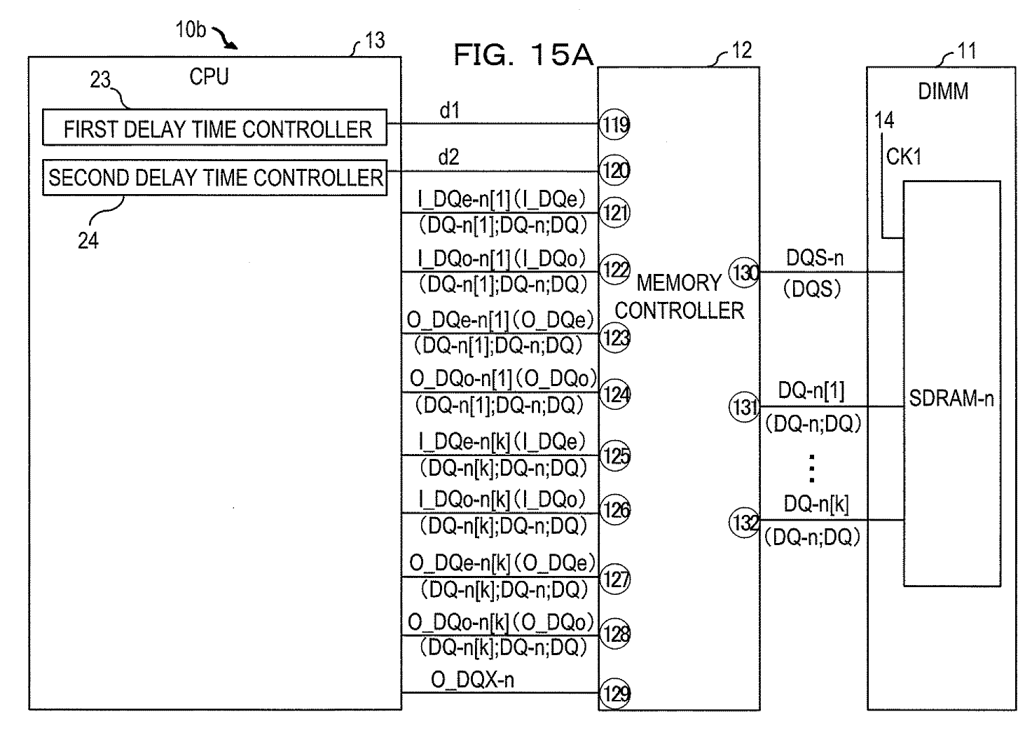

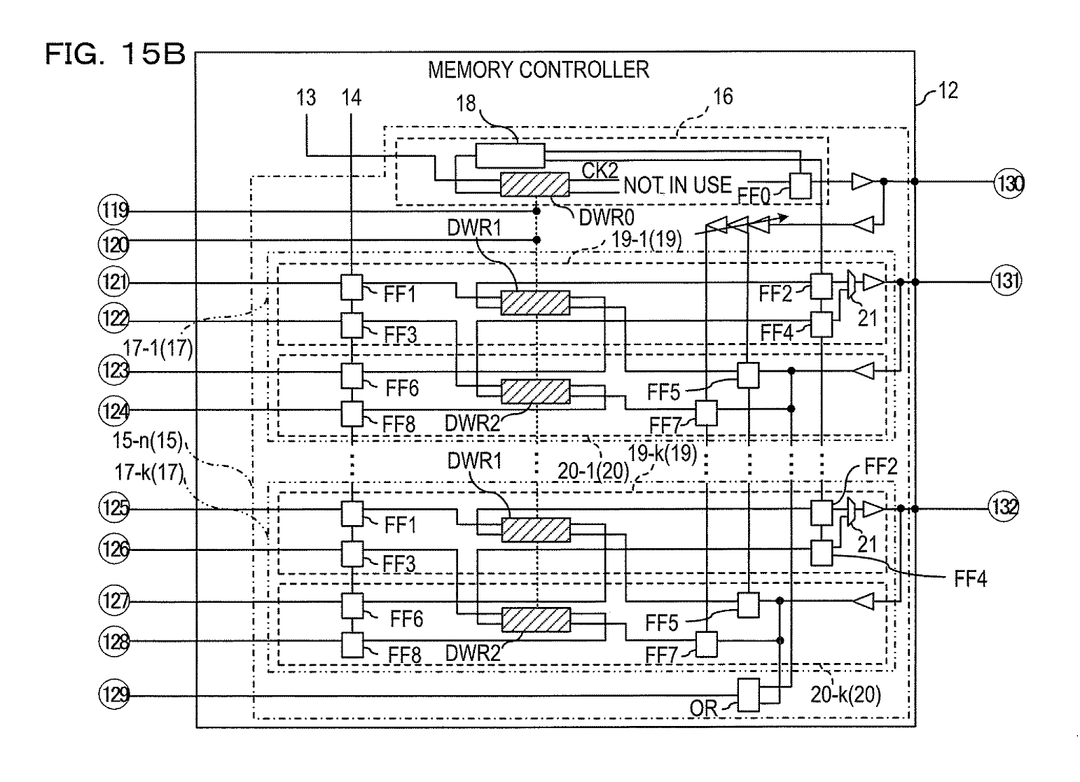

An information processing device 10b according to a second embodiment will be described with reference to FIGS. 14 and 15.

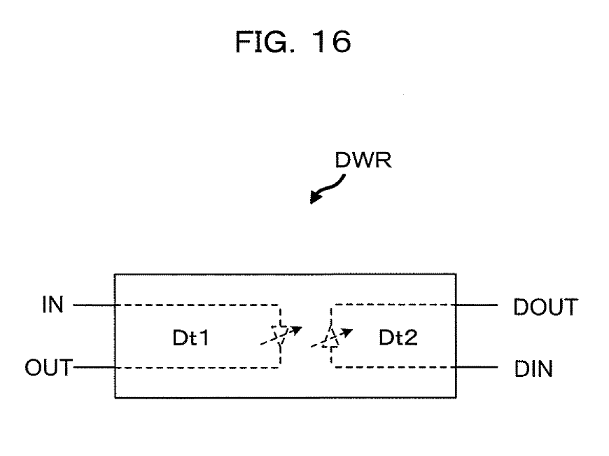

FIG. 14 is a circuit diagram showing a part corresponding to SDRAM-1 of the memory controller in the information processing device according to this embodiment. FIG. 15 is a circuit diagram showing a part corresponding to SDRAM-n. FIG. 16 is a diagram showing the function of a third variable delay circuit.

As shown in FIGS. 14 and 15, the information processing device 10b as this embodiment is equipped with a third variable delay circuit DWR0 in place of the first variable delay circuit DW0 provided to each of the control circuit units 15-1 to 15-n of the first embodiment, a third variable delay circuit (variable delay circuit) DWR1 in place of the first variable delay circuit DW1 and the second variable delay circuit DR1 provided to each of the control circuit units 15-1 to 15-n of the first embodiment, and a third variable delay circuit DWR2 in place of the first variable delay circuit DW2 and the second variable delay circuit DR2 provided to each of the control circuit units 15-1 to 15-n of the first embodiment. The other parts of the second embodiment have the same construction as the information processing device 10 of the first embodiment.

In the figures, the reference numerals same as the previously described reference numerals represent the same or substantially the same parts, and the detailed description thereof is omitted.

In the following description, with reference to reference character representing the third variable delay circuit of this embodiment, when it is necessary to specify one of plural third variable delay circuits, reference characters DWR0, DWR1, DWR2 are used. However, when any third variable delay circuit is indicated, reference character DWR is used.

The third variable delay circuit DWR of this embodiment is a digital delay circuit which can delay two signals at the same time. As shown in FIG. 16, the third variable delay circuit DWR is equipped with two input terminals IN and DIN and two output terminals OUT, DOUT, and a signal input from one input terminal IN is delayed by only the first delay time Dt1 set in the first delay time controller 23 and then output from one output terminal OUT. In addition, a signal input from the other input terminal DIN is delayed by only the second delay time Dt2 set in the second delay time controller 24 and then output from the other output terminal DOUT.

In the example shown in FIGS. 14 and 15, in the third variable delay circuit DWR0, the clock signal CLK from CPU 13 is input to one input terminal IN, delayed by only the first delay time Dt1, and then output from one output terminal OUT to the second clock signal generator 18. The other input terminal DIN and the other output terminal DOUT are not in use.

In the third variable delay circuit DWR1, the first data signal I_DQe is input from the flip flop FF1 to one input terminal IN, delayed by only the first delay time Dt1 and then output from one output terminal OUT to the flip flop FF2 as shown in FIGS. 14 and 15. Furthermore, the third data signal O_DQe is input from the flip flop FF5 to the other input terminal DIN, delayed by only the second delay time Dt2 and then output from the other output terminal DOUT to the flip flop FF6.

Furthermore, in the third variable delay circuit DWR2, the second data signal I_DQo is input from the flip flop FF3 to one input terminal IN, delayed by only the first delay time Dt1, and then output from one output terminal OUT to the flip flop FF4 as shown in FIGS. 14 and 15. Still furthermore, the fourth data signal O_DQo is input from the flip flop FF7 to the other input terminal DIN, delayed by only the second delay time Dt2, and then output from the other output terminal DOUT to the flip flop FF8.

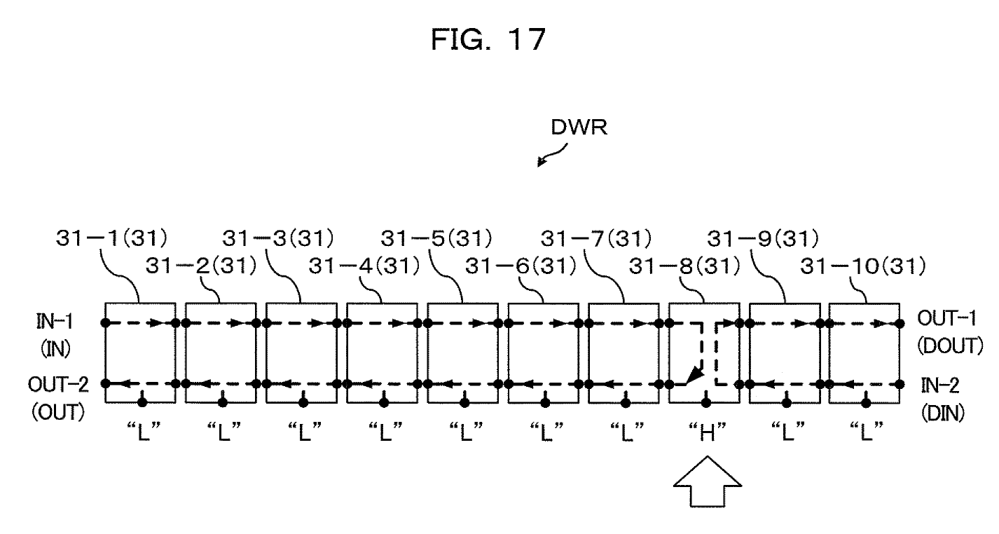

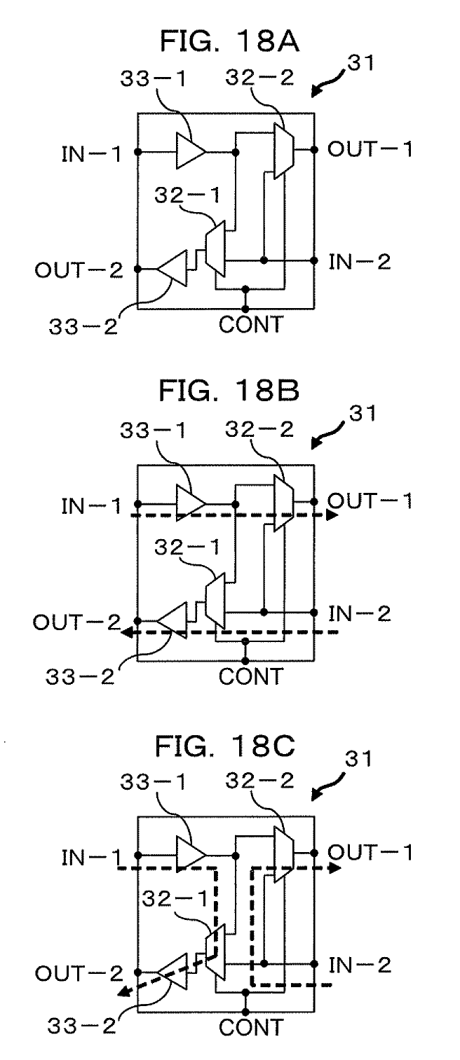

FIG. 17 is a schematic diagram showing an example of the construction of the third variable delay circuit in the information processing device according to the embodiment, FIGS. 18A to 18C are diagrams showing an example of the circuit construction of a unit circuit, wherein FIG. 18A is a diagram showing the construction of the unit circuit, FIG. 18B is a diagram showing a through operation mode of the unit circuit, and FIG. 18C is a diagram showing a feedback operation mode of the unit circuit.

The specific construction of the third variable delay circuit DWR will be described hereunder with reference to FIGS. 17 and 18. The third variable delay circuit DWR of this embodiment is constructed by connecting plural (for example, ten in the example of FIG. 17) unit circuits 31-1 to 31-10 in series.

With respect to a reference numeral representing a unit circuit, when it is necessary to specify one of plural unit circuits, reference numerals 31-1 to 31-10 are used. However, when any unit circuit is indicated, reference numeral 31 is used. The unit circuit 31 is a circuit which can switch a terminal from which an input signal is output, and as shown in FIG. 18A, it is equipped with a control signal input terminal CONT, a first selector (switching unit) 32-1, a second selector (switching unit) 32-2, a first input terminal IN-1, a second input terminal IN-2, a first output terminal OUT-1 and a second output terminal OUT-2.

The control signal input terminal CONT is a terminal to which control signals from the first delay time controller 23 and the second delay time controller 24 are input, and it is connected to a first selector 32-1 and a second selector 32-2 described later.

The first selector 32-1 switches a signal to be output on the basis of the control signal from the control signal input terminal CONT, and it is constructed by two input terminals and one output terminal.

The second selector 32-2 switches a signal to be output on the basis of the control signal from the control signal input terminal CONT, and it is constructed by two input terminals and one output terminal.

The first input terminal IN-1 is a terminal to which a first signal is input, and it is connected to one input terminal of the first selector 32-1 and one input terminal of the second selector 32-2 through an amplifier 33-1 as shown in FIG. 18A.

The second input terminal IN-2 is a terminal to which a second signal is input, and connected to the other input terminal of the first selector 32-1 and the other input terminal of the second selector 32-2 as shown in FIG. 18A.

The first output terminal OUT-1 is a terminal for selectively outputting the first signal input to the first input terminal IN-1 or the second signal input to the second input terminal IN-2, and it is connected to the output terminal of the second selector 32-2 as shown in FIG. 18A.

The second output terminal OUT-2 is a terminal for selectively outputting the first signal input to the first input terminal IN-1 or the second signal input to the second input terminal IN-2, and connected to the output terminal of the first selector 32-1 through an amplifier 33-2 as shown in FIG. 18A.

The unit circuit 31 is constructed to be operable selectively in any one of the through operation mode and the feedback operation mode on the basis of the control signal from the control signal input terminal CONT.

As shown in FIG. 18B, the through operation mode is a mode for outputting the first signal input from the first input terminal IN-1 to the first output terminal OUT-1, and also outputting the second signal input from the second input terminal IN-2 to the second output terminal OUT-2.

As shown in FIG. 18C, the feedback operation mode is a mode for outputting the first signal input from the first input terminal IN-1 to the second output terminal OUT-2 and outputting the second signal input from the second input terminal IN-2 to the first output terminal OUT-1.

In the third variable delay circuit DWR, as shown in FIG. 17 the plural unit circuits 31-1 to 31-10 are connected to one another in series, and the adjacent unit circuits 31 are connected to each other so that the first input terminal IN-1 and the first output terminal OUT-1 thereof are connected to each other and the second input terminal IN-2 and the second output terminal OUT-2 thereof are connected to each other.

That is, in the through operation mode, the first signal input from the unit circuit 31 at the front stage is output to the unit circuit 31 at the rear stage, and also the second signal input from the unit circuit 31 at the rear stage is output to the unit circuit 31 at the front stage. In the feedback operation mode, the first signal input from the unit circuit 31 at the front stage is output to the unit circuit 31 at the front stage, and the second signal input from the unit circuit 31 at the rear stage is output to the unit circuit 31 at the rear stage.

Furthermore, in this embodiment, the first delay time controller 23 carries out the control of delaying the first signal by only the first delay time Dt1 by passing the first signal through a part of the third variable delay circuit DWR, and the second delay time controller 24 carries out the control of delaying the second signal by only the second delay time Dt2 by passing the second signal through a part of the third variable delay circuit DWR.

Specifically, the first delay time controller 23 and the second delay time controller 24 output to each of the unit circuits 31-1 to 31-10 control signals for making one of the plural unit circuits 31-1 to 31-10 operate in the feedback operation mode and making the other unit circuits operate in the through operation mode on the basis of the first delay time Dt1 and the second delay time Dt2 corresponding to the first delay time Dt1 which are set by the first delay time controller 23 and the second delay time controller 24.

On the basis of the control signals output from the first delay time controller 23 and the second delay time controller 24 to the respective unit circuits 31-1 to 31-10, the third variable delay circuit DWR increases/reduces the number of unit circuits 31 through which the first signal input to the first input terminal IN-1 of the unit circuit 31-1 at the forefront stage or the second signal input to the second input terminal IN-2 of the unit circuit 31-10 at the last stage on the basis of the control signals output from the first delay time controller 23 and the second delay time controller 24 to the respective unit circuits 31-1 to 31-10, whereby the delay time from the input of the first signal and the second signal until the output thereof can be changed.

For example, as shown in FIG. 17, the first delay time controller 23 and the second delay time controller 24 output High signal to the unit circuit 31-8 on the basis of the first delay time Dt1 and the second delay time Dt2 set by the first delay time controller 23 and the second delay time controller 24, respectively. In addition, when Low signal is output to the unit circuits 31-1 to 31-7, 31-9, 31-10 other than the unit circuit 31-8, in the third variable delay circuit DWR, the unit circuit 31-8 operates in the feedback operation mode, and the unit circuits 31-1 to 31-7, 31-9, 31-10 operate in the through operation mode, thereby forming a first signal pass line and a second signal pass line.

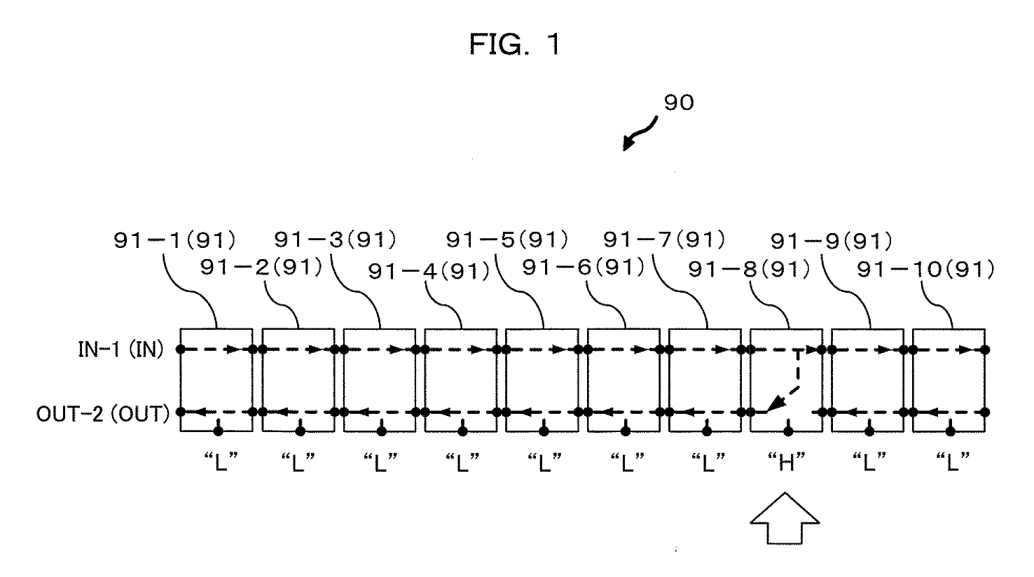

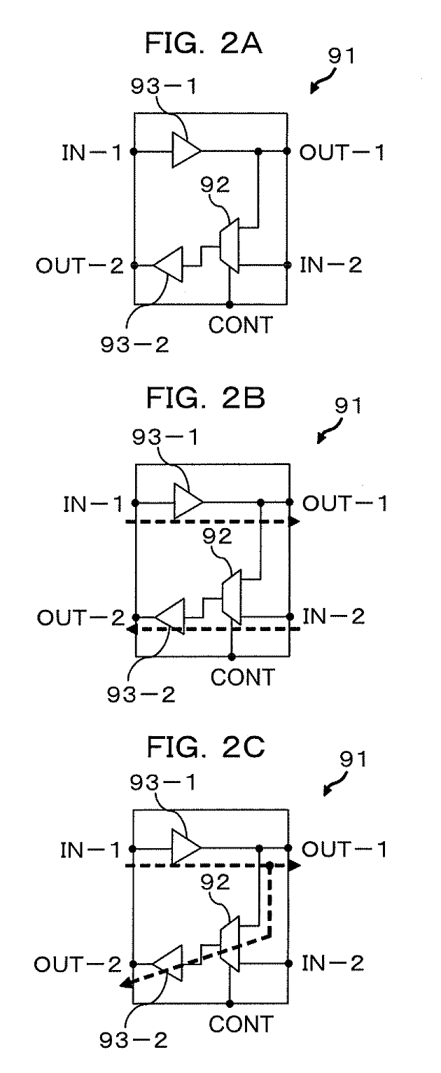

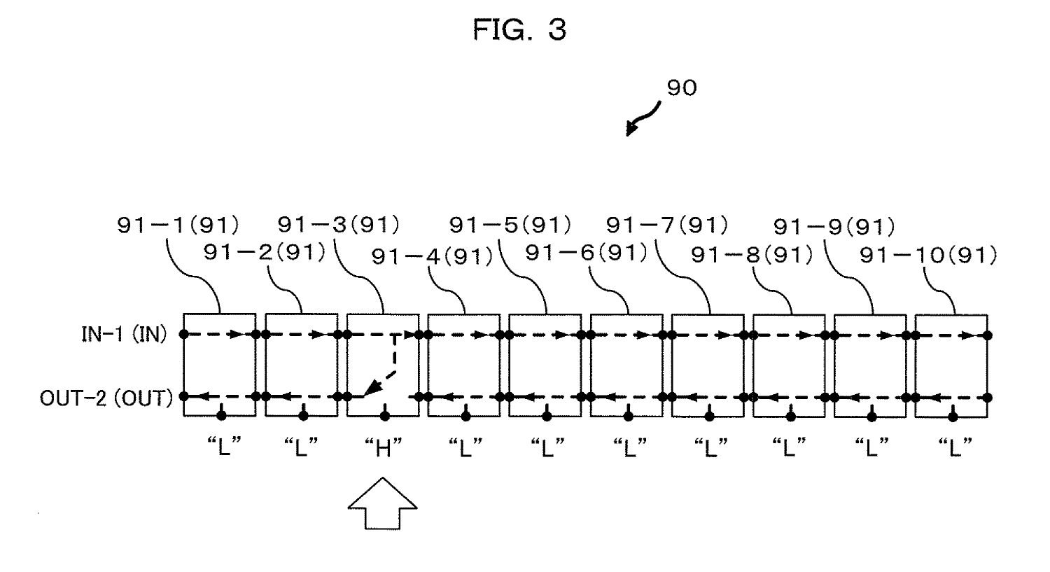

As shown in FIG. 1 7, in the first signal pass line, the first signal input from the first input terminal IN-1 of the unit circuit 31-1 at the forefront stage is successively passes through the plural unit circuits 31-2 to 31-7 operating in the through operation mode from the unit circuit 31-2 to the unit circuit 31-7, and returned from the unit circuit 31-8 operating in the feedback operation mode. Then, the first signal is successively passes through the plural unit circuits 31-2 to 31-7 operating in the through operation mode from the unit circuit 31-7 to the unit circuit 31-2, and output from the second output terminal OUT-2 of the unit circuit 31-1 at the forefront stage.

As shown in FIG. 17, in the second signal pass line, the second signal input from the second input terminal IN-2 of the unit circuit 31-10 at the last stage is passed through the unit circuit 31-9 operating in the through operation mode, returned from the unit circuit 31-8 operating in the feedback operation mode, passed through the unit circuit 31-9 operating in the through operation mode and then output from the first output terminal OUT-1 of the unit circuit 31-10 at the last stage.

Accordingly, the third variable delay circuit DWR provided to each of SDRAM-1 to SDRAM-n is controlled so that the sum of the first delay time Dt1 and the second delay time Dt2 thereof is fixed.

As described above, according to the information processing device 10b of the second embodiment, the same action and effect as the first embodiment can be obtained. Furthermore, the delay times Dt1, Dt2 from the input of two signals until the output thereof can be simultaneously delayed by using the unit circuits which are constructed so as to be operable while selecting one of the through operation mode in which the signal input from the unit circuit 31 at the front stage is output to the unit circuit 31 at the rear stage and also the signal input from the unit circuit 31 at the rear stage is output to the unit circuit 31 at the front stage, and the feedback operation mode in which the signal input from the unit circuit 31 at the front stage is output to the unit circuit 31 at the front stage and also the signal input from the unit circuit 31 at the rear stage is output to the unit circuit 31 at the rear stage. Accordingly, the delay times Dt1, Dt2 from the input of the signal until the output thereof can be efficiently set, needless power consumption and occupation area can be reduced and the manufacturing cost can be reduced.

Furthermore, at least one unit circuit 31 of the plural unit circuits 31-1 to 31-10 operates in the feedback operation mode, whereby the respective delay times Dt1, Dt2 of the two signals can be easily set under the state that the sum of the delay times Dt1, Dt2 of the two signals is kept constant.

Still furthermore, the sum of the first delay time Dt1 of the first signal and the second delay time Dt2 of the second signal is controlled to be equal to a preset value, and the sum of the first delay time Dt1 of the first signal and the second delay time Dt2 of the second signal is controlled to be fixed, whereby the respective delay times of two signals can be easily set under the state that the sum of the delay times of the two signals is kept constant.

### Description of Modification of Second Embodiment

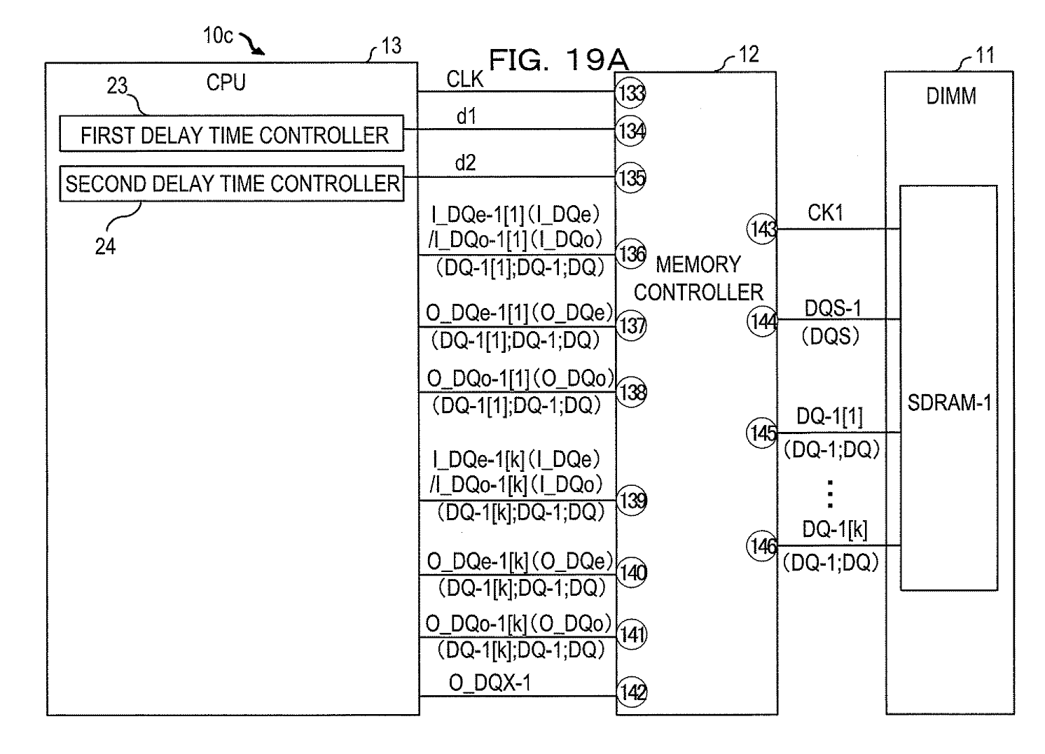

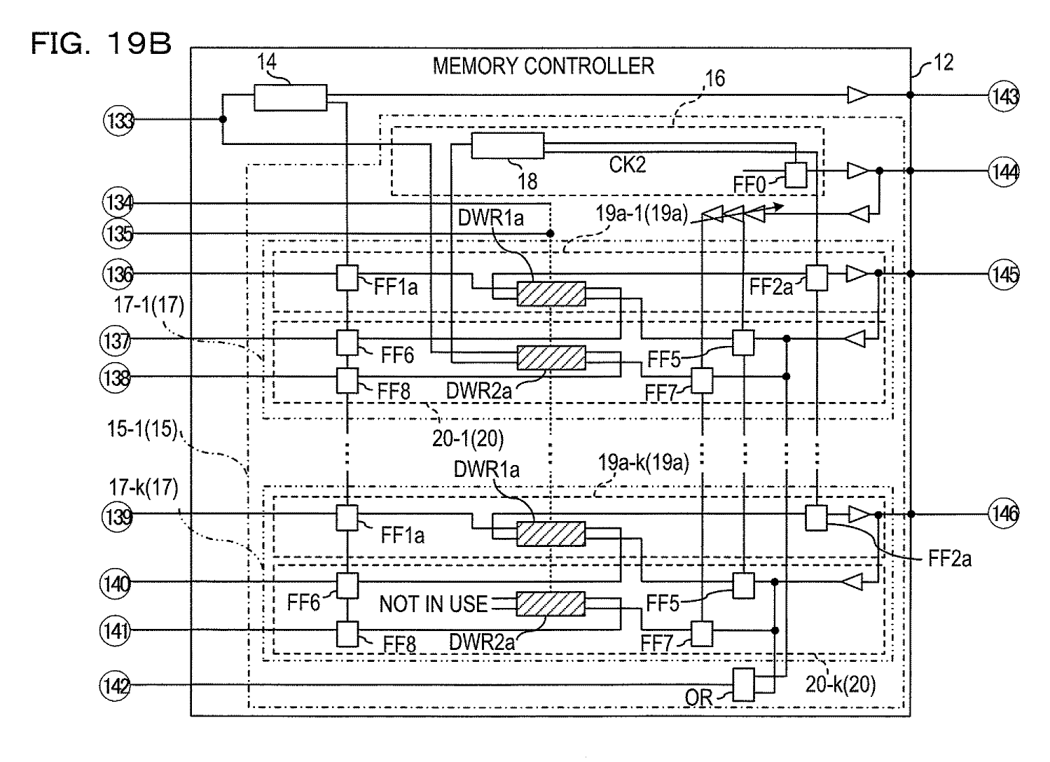

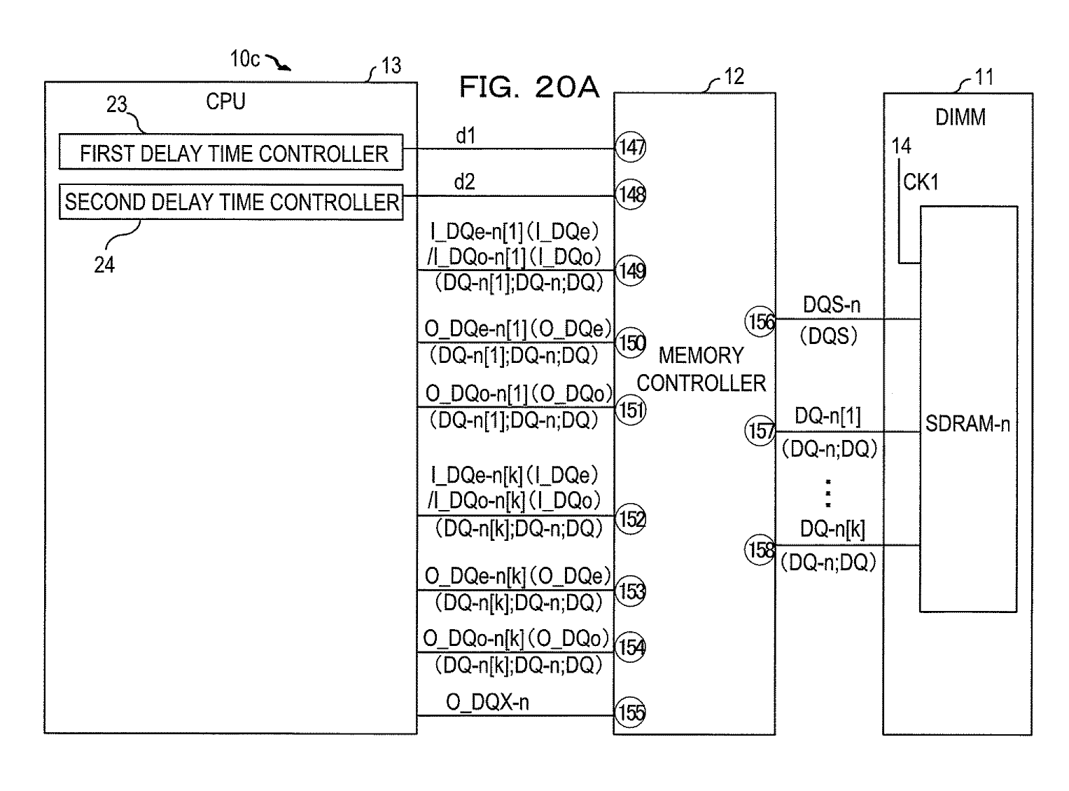

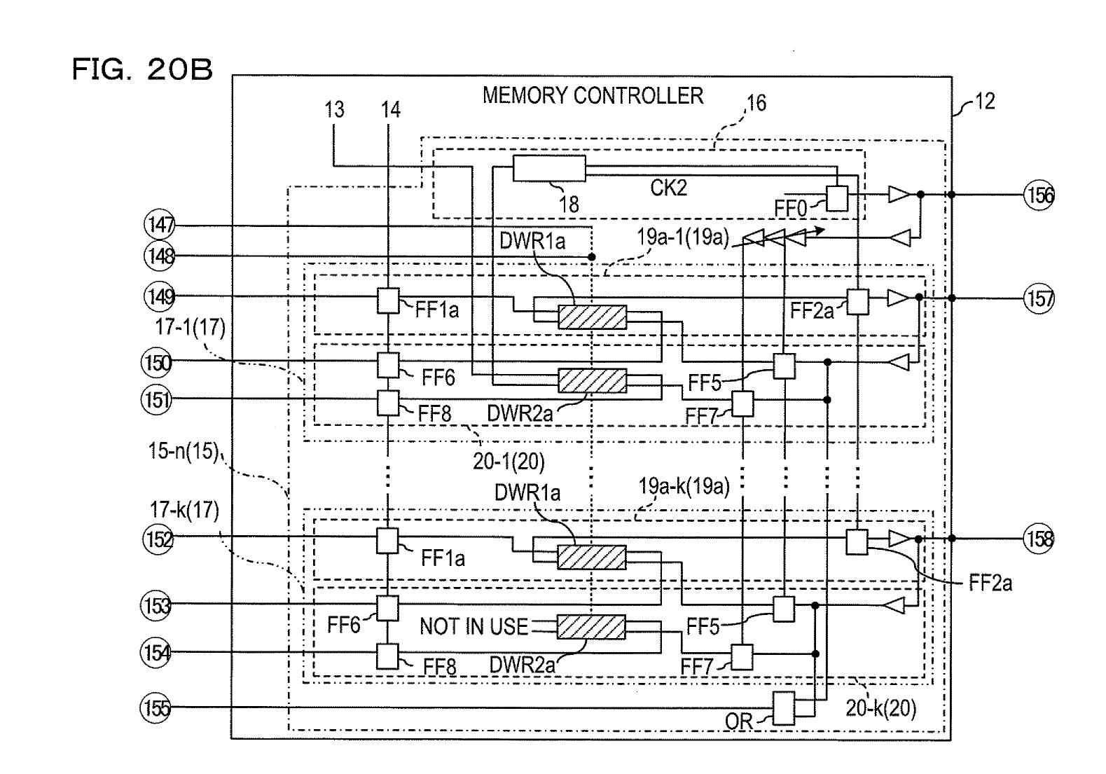

A modification of the information processing device 10b according to the second embodiment will be described with reference to FIGS. 19 and 20.

FIG. 19 is a circuit diagram showing a part corresponding to SDRAM-1 of a memory controller in an information processing device as a modification of the second embodiment, and FIG. 20 is a circuit diagram showing a part corresponding to SDRAM-n of the modification of the second embodiment.

As shown in FIGS. 19 and 20, the information processing device 10c as the modification of the second embodiment is equipped with DQ signal input controllers 19a-1 to 19a-k in place of the DQ signal input controllers 19-1 to 19-k in the respective control circuit units 15-1 to 15-n of the first embodiment as in the case of the modification of the first embodiment. In connection with this change, the information processing device 10c is equipped with third variable delay circuits DWR1a, DWR2a in place of the third variable delay circuits DWR0, DWR1, DWR2 provided to the respective control circuit units 15-1 to 15-n of the first embodiment. The other parts are designed in the same construction as the information processing device 10a of the modification of the first embodiment, or the information processing device 10b of the second embodiment.

In the figures, the reference numerals same as the previously described reference numerals represent the same or substantially the same parts, and thus the detailed description thereof is omitted.

With respect to reference character representing the third variable delay circuit as the modification of the second embodiment, when it is necessary to specify one of the plural third variable delay circuits, reference characters DWR1a, DWR2a are used. However, when any third variable delay circuit is indicated, reference character DWR is used.

Furthermore, the third variable delay circuit DWR in the modification of the second embodiment has the same function and construction as the third variable delay circuit DWR of the second embodiment, and the detailed description thereof is omitted.

In the third variable delay circuit DWR1 a, as shown in FIGS. 19 and 20, the first data signal I_DQe or the second data signal I_DQo is input from the flip flop FF1a to one input terminal IN, delayed by only the first delay time Dt1 and then output from one output terminal OUT to the flip flop FF2a. The third data signal O_DQe is input from the flip flop FF5 to the other input terminal DIN, delayed by only the second delay time Dt2 and then output from the other output terminal DOUT to the flip flop FF6.

In the third variable delay circuit DWR2a provided to the DQ signal controller 17-1, as shown in FIGS. 19 and 20, the clock signal CLK is input from CPU 13 to one input terminal IN, delayed by only the first delay time Dt1 and then output from one output terminal OUT to the second clock signal generator 18. The fourth data signal O_DQo is input from the flip flop FF7 to the other input terminal DIN, delayed by only the second delay time Dt2 and then output from the other output terminal DOUT to the flip flop FF8.

In the third variable delay circuit DWR2a provided to each of the DQ signal controllers 17-2 to 17-n other than the DQ signal controller 17-1, as shown in FIGS. 19 and 20, one input terminal DIN and one output terminal DOUT are not in use, and the fourth data signal O_DQo is input from the flip flop FF7 to the other input terminal DIN, delayed by only the second delay time Dt2 and then output from the other output terminal DOUT to the flip flop FF8.

As described above, the same action and effect as the second embodiment described above can be obtained by using the information processing device 10c as the modification of the second embodiment.

### Other Embodiments

The present circuit is not limited to the above second embodiment, and various modifications may be made without departing from the subject matter.

For example, the memory controller 12 is not limited to the circuit described in the above embodiment, and various kinds of DDR3 memory interfaces in which the third variable delay circuit DWR can be mounted can be applied.

In the above embodiment, the third variable delay circuit DWR provided to each of SDRAM-1 to SDRAM-n is controlled so that the sum of the first delay time Dt1 and the second delay time Dt2 is fixed, however, the present circuit is not limited to the embodiment. For example, the first and second delay times Dt1 and Dt2 may be set to preset values insofar as the sum thereof is not more than the maximum delay time in the third variable delay circuit DWR.

In the above embodiment, the control signal for making one of the plural unit circuits 31-1 to 31-10 operate in the feedback operation mode and making the other unit circuits operate in the through operation mode is output to each of the unit circuit 31-1 to 31-10.

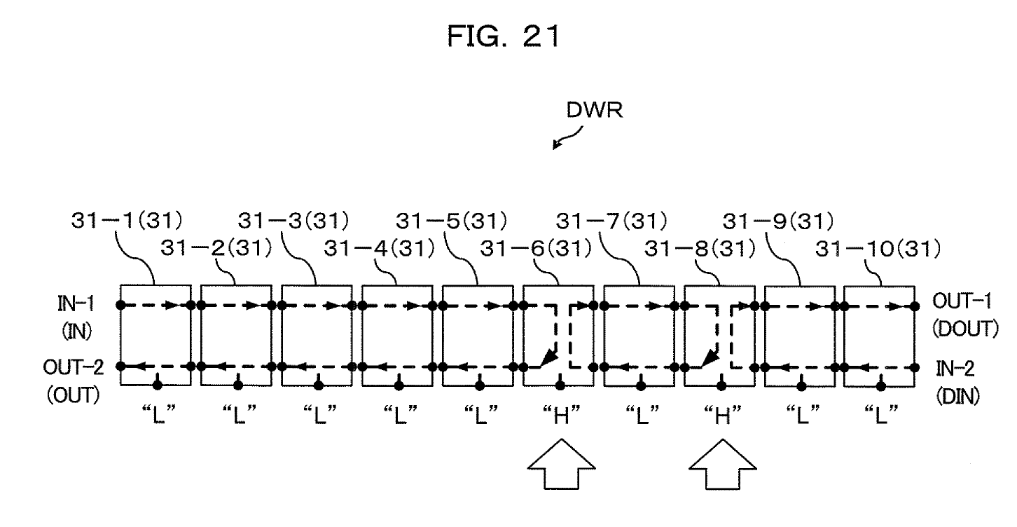

FIG. 21 is a diagram showing an example in which the third variable delay circuit in the information processing device of the above embodiment is used in another style.

For example, as shown in FIG. 21, a control signal for making plural unit circuits 31-6, 31-8 out of the plural unit circuits 31-1 to 31-10 operate in the feedback operation mode may be output to each of the unit circuits 31-1 to 31-10. In this case, as shown in FIG. 21, in the first signal pass line, the first signal input from the unit circuit 31-1 at the forefront stage is returned from the unit circuit 31-6 which operates in the feedback operation mode and is nearest to the unit circuit 31-1 at the forefront stage, and then output from the unit circuit 31-1 at the forefront stage. Furthermore, in the second signal pass line, the second signal input from the unit circuit 31-10 at the last stage is returned from the unit circuit 31-8 which operates in the feedback operation mode and is nearest to the unit circuit 31-10 at the last stage, and then output from the unit circuit 31-10 at the last stage. Accordingly, the sum of the respective delay times of two signals can be easily changed in accordance with the temperature or voltage.

CPU 13 functions as the first delay time controller 23 and the second delay time controller 24 by executing a delay time control program.

The program (delay time control program) for implementing the functions of the first delay time controller 23 and the second delay time controller 24 is provided in a recording style that it is recorded in a computer-readable recording medium such as a flexible disc, CD (CD-ROM, CD-R, CD-RW or the like), DVD (DVD-ROM, DVD-RAM, DVD-R, DVD+R, DVD-RW, DVD+RW, HD-DVD or the like), Blu-ray Disc, a magnetic disc, an optical disc, a magnetooptical disc or the like. A computer reads the program form the recording medium, and transfers and stores the program into an internal storage device or external storage device. The program may be recorded in a storage device (recording medium)such as a magnetic disc, an optical disc, a magnetooptical disc or the like, and supplied from the storage device through a communication path to a computer.

When the functions as the first delay time controller 23 and the second delay time controller 24 are implemented, the program stored in the internal storage device may be executed by the microprocessor of the computer. At this time, the program recorded in the recording medium may be read out and executed by the computer.

In the first and second embodiments, the computer is defined as a concept containing a hardware and an operating system, and it means the hardware operating under the control of the operating system. Furthermore, when the operating system is unnecessary and the hardware is operated by only an application program, the hardware itself corresponds to the computer. The hardware has at least a microprocessor such as CPU or the like, and means for reading a computer program recorded in a recording medium, and the information processing devices 10, 10a, 10b, 10c have the function as a computer.

Furthermore, as the recording medium of the first and second embodiments may be used various kinds of computer-readable media such as an IC card, a ROM cartridge, a magnetic tape, a punch card, an internal storage device of a computer (a memory such as RAM, ROM or the like), an external storage device, a print matter having characters such as bar codes or the like printed thereon or the like in addition to a flexible disc, CD, DVD, Blu-ray Disc, a magnetic disc, an optical disc, a magnetooptical disc, etc.

Further, according to an aspect of the embodiments, any combinations of the described features, functions and/or operations can be provided.

The many features and advantages of the embodiments are apparent from the detailed specification and, thus, it is intended by the appended claims to cover all such features and advantages of the embodiments that fall within the true spirit and scope thereof. Further, since numerous modifications and changes will readily occur to those skilled in the art, it is not desired to limit the inventive embodiments to the exact construction and operation illustrated and described, and accordingly all suitable modifications and equivalents may be resorted to, falling within the scope thereof.

What is claimed is:

1. A variable delay circuit that is constructed by connecting plural unit circuits in series and can change a delay time from input of a signal until output of the signal by increasing or decreasing the number of unit circuits through which the signal concerned is passed, wherein each of the unit circuits is operable in selected one of a through operation mode in which a signal input from a unit circuit at the front stage is output to a unit circuit at the rear stage and also a signal input from a unit circuit at the rear stage is output to a unit circuit at the front stage and a feedback operation mode in which a signal input from a unit circuit at the front stage to a unit circuit at the front stage and a signal input from a unit circuit at the rear stage is output to a unit circuit at the rear stage.

2. The variable delay circuit according to claim 1, wherein the unit circuit has a switching unit for selectively switching the through operation mode and the feedback operation mode to each other in accordance with a control signal.

3. The variable delay circuit according to claim 1, wherein at least one of the plural unit circuits operates in the feedback operation mode, whereby a first signal pass line in which a first signal input from the unit circuit at the forefront stage is returned from a unit circuit operating in the feedback operation mode and then output from the unit circuit at the forefront stage, and a second signal pass line in which a second signal input from the unit circuit at the last stage is returned from a unit circuit operating in the feedback operation mode and then output from the unit circuit at the last stage are formed.

4. The variable delay circuit according to claim 1, wherein some of unit circuits out of the plural unit circuits operate in the feedback operation mode, whereby a first signal pass line in which a first signal input from the unit circuit at the forefront stage is returned from a unit circuit which operates in the feedback operation mode and is nearest to the unit circuit at the forefront stage, and then output from the unit circuit at the forefront stage, and a second signal pass line in which a second signal input from the unit circuit at the last stage is returned from a unit circuit which operates in the feedback operation mode and is nearest to the unit circuit at the last stage, and then output from the unit circuit at the last stage.

5. A delay time control method for controlling a delay time by using a variable delay circuit that is constructed by connecting plural unit circuits in series and can change a delay time from input of a signal until output of the signal by increasing or decreasing the number of unit circuits through which the signal concerned is passed, each of the unit circuits being operable in selected one of a through operation mode in which a signal input from a unit circuit at the front stage is output to a unit circuit at the rear stage and also a signal input from a unit circuit at the rear stage is output to a unit circuit at the front stage and a feedback operation mode in which a signal input from a unit circuit at the front stage to a unit circuit at the front stage and a signal input from a unit stage at the rear stage is output to a unit circuit at the rear stage, comprising:
a first delay time control operation of delaying the first signal by only the first delay time by passing the first signal through a part of the variable delay circuit; and
a second delay time control operation of delaying the second signal by only the second delay time by passing the second signal through a part of the variable delay circuit.

6. The delay time control method according to claim 5, wherein in the first delay time control operation and the second delay time control operation, the first delay time and the second delay time are controlled so that the sum of the first delay time and the second delay time is equal to a preset value.

7. The delay time control method according to claim 5, wherein in the first delay time control operation and the second delay time control operation, the first delay time and the second delay time are controlled so that the sum of the first delay time and the second delay time is fixed.

8. The delay time control method according to claim 5, wherein in the first delay time control operation and the second delay time control operation, the first delay time and the second delay time are controlled so that the sum of the first delay time and the second delay time is not more than the maximum delay time of the variable delay circuit.

9. A unit circuit constituting a variable delay circuit that can change a delay time from input of a signal until output of the signal by increasing or decreasing the number of unit circuits through which the signal is passed, the unit circuit being operable in selected one of a through operation mode in which a signal input from a unit circuit at the front stage is output to a unit circuit at the rear stage and also a signal input from a unit circuit at the rear stage is output to a unit circuit at the front stage and a feedback operation mode in which a signal input from a unit circuit at the front stage is output to a unit circuit at the front stage and a signal input from a unit stage at the rear stage is output to a unit circuit at the rear stage.

10. The unit circuit according to claim 9, further comprising a switching unit for selectively switching the through operation mode and the feedback operation mode to each other in accordance with a control signal.
